(19) United States
(12) Patent Application Publication
(10) Pub. No.: US 2024/0112930 A1
(43) Pub. Date: Apr. 4, 2024

(54) CHAMBER ARRANGEMENTS WITH LASER SOURCES, SEMICONDUCTOR PROCESSING SYSTEMS, AND MATERIAL LAYER DEPOSITION METHODS

(71) Applicant: ASM IP Holding, B.V., Almere (NL)

(72) Inventors: Fan Gao, Chandler, AZ (US); Peipei Gao, Chandler, AZ (US); Wentao Wang, Chandler, AZ (US); Kai Zhou, Phoenix, AZ (US); Kishor Patil, Chandler, AZ (US); Han Ye, Phoenix, AZ (US); Xing Lin, Chandler, AZ (US); Alexandros Demos, Scottsdale, AZ (US)

(21) Appl. No.: 18/476,117

(22) Filed: Sep. 27, 2023

Related U.S. Application Data
(60) Provisional application No. 63/377,757, filed on Sep. 30, 2022.

(51) Int. Cl. H01L 21/67; B23K 26/03; B23K 26/06; C23C 16/458; C23C 16/46; C23C 16/48; C23C 16/52; G05D 23/19

(52) U.S. Cl. CPC H01L 21/67115; B23K 26/034; B23K 26/0626; B23K 26/0643; C23C 16/4584; C23C 16/46; C23C 16/483; C23C 16/52; G05D 23/1931; H01L 21/67109

(57) ABSTRACT

A chamber arrangement includes a chamber body, a substrate support, and a laser source. The substrate support is arranged within the chamber body and supported for rotation about a rotation axis relative to the chamber body. The laser source is arranged outside of the chamber body and optically coupled to the substrate support along a lasing axis. The lasing axis intersects the substrate support at a location radially outward from an outer periphery of a substrate seated on the substrate support. A semiconductor processing system and a material layer deposition method are also described.

### CROSS-REFERENCE TO RELATED APPLICATION(S)

This application claims the benefit of U.S. Provisional Application 63/377,757 filed on Sep. 30, 2022, the entire contents of which are incorporated herein by reference.

### FIELD OF INVENTION

The present disclosure generally relates to depositing material layers onto substrates, and more particularly, to controlling the temperature of substrates during the deposition of material layers onto substrates such as during the fabrication of semiconductor devices.

### BACKGROUND OF THE DISCLOSURE

Semiconductors devices are commonly fabricated by depositing material layers onto substrates. Material layers is generally accomplished by support a substrate in a process module, heating the substrate to a desired deposition temperature, and exposing the substrate to a material layer precursor. Exposure of the substrate to the material layer precursor causes a material layer to develop on the substrate, typically according to temperature of the substrate while exposed to the material layer precursor. Once the material layer reaches a desired thickness, exposure of the substrate to the material layer ceases, the substrate cooled, the substrate thereafter removed from the process chamber, and the substrate sent on for further processing.

In some material layer deposition techniques, variation in the properties of the material layer deposited onto the substrate due to heating variation may influence reliability of semiconductor devices formed using the substrate. For example, substrates having patterns may exhibit emissivity adjacent to the periphery of the substrate (wherein the pattern may be discontinuous) differing from that of the interior region of the substrate (where the pattern may be contiguous). The emissivity differences may, in some material layer depositions, cause temperature at the periphery of the substrate to differ from temperature of the substrate at the interior region of the substrate. The temperature differential may, in turn, cause properties of the deposited material layer to differ in the vicinity of the periphery of the substrate relative to thickness of the material layer on the interior region of the substrate. For example, the material layer may thicken or thin adjacent the periphery of the substrate relative to thickness of the material layer at the interior region of the substrate. The differing material layer properties may, during the fabrication of some semiconductor devices, cause differences in performance between semiconductor devices fabricated adjacent to the periphery of the substrate in relation to semiconductor devices fabricated within the interior region of the substrate.

Various countermeasures exist to limit heating variation in substrates. For example, material layer precursor distribution within the process chamber may be varied to offset variation in the material layer adjacent to the periphery of the substrate relative to the interior region of the substrate otherwise characteristic of the material layer deposition technique. Heating of the substrate may be varied to offset variation in the material layer adjacent to the periphery of the substrate relative to the interior region of the substrate otherwise characteristic of the material layer deposition technique, for example, by independently controlling heater elements according to location relative to the substrate. And patterning responsible for emissivity may be extended outward toward the periphery of the substrate to increase size of the interior region of the substrate relative to size of the region adjacent the periphery to reduce the number of semiconductor devices impacted by the material layer variation adjacent to the periphery of the substrate.

Such systems and methods have generally been acceptable for their intended purpose. However, there remains a need in the art for improved chamber arrangements, semiconductor processing systems having chamber arrangements, and methods of depositing material layers onto substrates. The present disclosure provides a solution to this need.

### SUMMARY OF THE DISCLOSURE

A chamber arrangement is provided. The chamber arrangement includes a chamber body, a substrate support, and a laser source. The substrate support is arranged within the chamber body and supported for rotation about a rotation axis relative to the chamber body. The laser source is arranged outside of the chamber body and optically coupled to the substrate support along a lasing axis. The lasing axis intersects the substrate support at a location radially outward from an outer periphery of a substrate seated on the substrate support.

In addition to one or more of the features described above, or as an alternative, further examples of the chamber arrangement may include that the lasing axis intersects the substrate support at a radial offset that is between about 150 millimeters and about 200 millimeters, or is between about 151 millimeters and about 170 millimeters, or is between about 151 millimeters and about 155 millimeters.

In addition to one or more of the features described above, or as an alternative, further examples of the chamber arrangement may include one or more lens element arranged along the lasing axis and coupling the laser source to both a peripheral portion of the substrate and the substrate support through an upper wall of the chamber body.

In addition to one or more of the features described above, or as an alternative, further examples of the chamber arrangement may include that the lens element defines a lasing spot overlaying a portion of the substrate and an adjacent portion of the substrate support.

In addition to one or more of the features described above, or as an alternative, further examples of the chamber arrangement may include that the lasing spot has a width that is between about 5 millimeters and about 50 millimeters, or between about 10 millimeters and about 40 millimeters, or is between about 15 millimeters and about 30 millimeters.

In addition to one or more of the features described above, or as an alternative, further examples of the chamber arrangement may include that the lens element defines a focal point, wherein the focal point is defined outside of the chamber body.

In addition to one or more of the features described above, or as an alternative, further examples of the chamber arrangement may include a reflector body supported above the chamber body and having a lasing aperture extending therethrough, wherein the lasing axis extends through the lasing aperture.

In addition to one or more of the features described above, or as an alternative, further examples of the chamber arrangement may include that the lasing aperture has a width that is between about 2 millimeters and about 20 millimeters, or that is between about 4 millimeters and about 15 millimeters, or that is between about 4 millimeters and about 10 millimeters.

In addition to one or more of the features described above, or as an alternative, further examples may include that the lasing aperture is spaced apart from the substrate support by between about 10 millimeters and about 100 millimeters, or by between about 10 millimeters and about 60 millimeters, or by between about 10 millimeters and about 40 millimeters.

In addition to one or more of the features described above, or as an alternative, further examples of the chamber arrangement may include a lens element arranged along the lasing axis and above the reflector body The lens element may have a focal point. The focal point may be defined within the lasing aperture.

In addition to one or more of the features described above, or as an alternative, further examples of the chamber arrangement may include a mount arranged along the lasing axis. The mount may defines a bore therethrough that optically couples the laser source to both the substrate support and the substrate.

In addition to one or more of the features described above, or as an alternative, further examples of the chamber arrangement may include a lens element and a reflector body. The lens element may be seated on the mount. The mount may be supported by reflector body, the reflector body may have a lasing aperture, and the mount may register the lens element to the lasing aperture such that the bore optically couples the lens element to the lasing aperture. The lasing aperture and the bore may be fluidly separated from a coolant source plenum bounded by a mounting surface of the reflector body by the mount. The lasing aperture may fluidly couple the bore to a coolant supply plenum defined between a reflective surface and the chamber body.

In addition to one or more of the features described above, or as an alternative, further examples of the chamber arrangement may include a first sealing member arranged between the lens element and the mount and a second sealing member arranged between the mount and the reflector body. The first sealing member may fluidly separate the bore from the coolant source plenum, the second sealing member may fluidly separating the bore from the coolant source plenum, and the reflector body may define one or more one slot therethrough fluidly coupling the coolant source plenum to the coolant supply plenum such that the bore is fluidly coupled through the coolant supply plenum and the slot to the coolant source plenum.

In addition to one or more of the features described above, or as an alternative, further examples of the chamber arrangement may include an interlock switch connected to the mount and the lens element. The interlock switch may be operably connected to the laser source to remove power from the laser source when the lens element is separated from the mount.

In addition to one or more of the features described above, or as an alternative, further examples of the chamber arrangement may include that the interlock switch includes a mount portion fixed relative to the mount and a lens portion fixed relative to the lens element. The lens portion of the interlock switch may be electromagnetically coupled to the mount portion of the interlock switch when the lens element is seated in the mount.

In addition to one or more of the features described above, or as an alternative, further examples of the chamber arrangement may include a temperature sensor operably connected to the laser source.

In addition to one or more of the features described above, or as an alternative, further examples of the chamber arrangement may include that the temperature sensor includes a rotating thermocouple arranged within the interior of the chamber body and fixed in rotation relative to the substrate support.

In addition to one or more of the features described above, or as an alternative, further examples may include a rotating thermocouple and a static thermocouple. The rotating thermocouple may be arranged within the chamber body and fixed relative to the substrate support for rotating with the substrate about the rotation axis to provide a center temperature measurement of the substrate. The static thermocouple may be arranged within the interior of the chamber body and fixed relative to the chamber body. The static thermocouple may be arranged radially outward of the substrate support to provide an edge temperature measurement of the substrate.

In addition to one or more of the features described above, or as an alternative, further examples of the chamber arrangement may include that the temperature sensor includes a pyrometer. The pyrometer may be supported above the chamber body and arranged along an optical axis intersecting the substrate support. The optical axis may be radially inward of the lasing axis to acquire a center temperature measurement of a central portion the substrate.

In addition to one or more of the features described above, or as an alternative, further examples of the chamber arrangement may include that the pyrometer is a center pyrometer arranged along a center optical axis and the temperature sensor further includes an edge pyrometer. The edge pyrometer may be supported above the chamber body and arranged along an edge optical axis. The edge optical axis may intersect the substrate support radially inward of the center optical axis to acquire an edge temperature measurement of a peripheral portion of the substrate.

In addition to one or more of the features described above, or as an alternative, further examples of the chamber arrangement may include a middle pyrometer. The middle pyrometer may be supported above the chamber body and arranged along a middle optical axis. The middle optical axis may intersect the substrate support radially between the center optical axis and the edge optical axis to acquire a middle temperature measurement of the central portion of the substrate.

In addition to one or more of the features described above, or as an alternative, further examples may include a controller operably connected to the laser source. The controller may be responsive to instructions recorded on a memory to seat the substrate on the substrate support; heat the substrate and the substrate support using an upper heater element array supported above the chamber body and a lower heater element array supported below the chamber body; further heat a peripheral portion of the substrate and an adjacent portion of the substrate using laser illumination from the laser source; expose the substrate to a material layer precursor; and deposit a material layer onto the substrate using the material layer precursor while heating the substrate with the upper heater element array, the lower heater element array, and the laser source.

In addition to one or more of the features described above, or as an alternative, further examples may include that the laser source has a wavelength that is between about 700 nanometers and about 900 nanometers, or is between about 740 nanometers and about 860 nanometers, or is between about 780 nanometers and about 820 nanometers.

In addition to one or more of the features described above, or as an alternative, further examples may include that the laser source has an output power than is between about 140 watts and about 200 watts, or that is between about 150 watts and about 190 watts, or that is between about 160 watts and about 180 watts.

A semiconductor processing system is provided. The semiconductor processing system includes a precursor delivery arrangement including a silicon-containing precursor and a chamber arrangement as described above connected to the precursor delivery arrangement. The substrate support is configured to support an edge or bevel of the substrate during deposition of an epitaxial material layer onto an upper surface of the substrate using the silicon-containing precursor. One or more lens element optically coupling the laser source to the substrate support through an upper wall of the chamber body is arranged along the lasing axis. A reflector body having an aperture extending is supported above the chamber body, the lasing axis extending through the aperture. A mount defining a bore therethrough is arranged along the lasing axis, the bore optically coupling the laser source to the substrate support, a temperature sensor is operably connected to the laser source and configured to acquire a temperature of the substrate seated on the substrate support, and a controller is operably connected to the laser source and disposed in communication with the temperature sensor. The controller is responsive to instructions recorded on a memory to seat the substrate on the substrate support; heat the substrate and the substrate support using an upper heater element array supported above the chamber body and a lower heater element array supported below the chamber body; further heat a peripheral portion of the substrate and an adjacent portion of the substrate using laser illumination from the laser source; expose the substrate to a material layer precursor; and deposit a material layer onto the substrate using the material layer precursor while heating the substrate with the upper heater element array, the lower heater element array, and the laser source.

In addition to one or more of the features described above, or as an alternative, further examples of the semiconductor processing system may include a temperature sensor having a rotating thermocouple fixed relative to the substrate support and a static thermocouple fixed relative to the chamber body. The rotating thermocouple and the static thermocouple may both operably connected to the laser source.

In addition to one or more of the features described above, or as an alternative, further examples of the semiconductor processing system may include a temperature sensor having a center pyrometer supported above the chamber body and optically coupled to a central portion of the substrate by a center optical axis, an edge pyrometer supported above the chamber body and optically coupled to the peripheral portion of the substrate by an edge optical axis, and a middle pyrometer supported above the chamber body and optically coupled to the central portion of the substrate by a middle optical axis. The edge optical axis may be located radially between the lasing axis and the rotation axis; the middle optical axis may be located radially between the center optical axis and the edge optical axis; and the center pyrometer, the edge pyrometer, and the middle pyrometer may each be operably connected to the laser source.

A material layer deposition method is provided. The method includes, at a chamber arrangement as described above, seating the substrate on the substrate support, heating the substrate and the substrate support using an upper heater element array supported above the chamber body and a lower heater element array supported below the chamber body, and further heating a peripheral portion of the substrate and an adjacent portion of the substrate using laser illumination from the laser source. The substrate is exposed to a material layer precursor; and a material layer deposited onto the substrate using the material layer precursor while heating the substrate with the upper heater element array, the lower heater element array, and the laser source.

In addition to one or more of the features described above, or as an alternative, further examples may include throttling the laser illumination using a temperature measurement acquired from one of a thermocouple fixed relative to the substrate support and a pyrometer supported above the chamber body and optically coupled to the substrate by an optical axis.

In addition to one or more of the features described above, or as an alternative, further examples may include acquiring a center temperature measurement using a center pyrometer supported above the chamber body and optically coupled to a center portion of the substrate by a center optical axis, acquiring an edge temperature measurement using an edge pyrometer supported above the chamber body optically coupled to a peripheral portion of the substrate by an edge optical axis, and determining a center-to-edge temperature differential using the center temperature measurement and the edge temperature measurement. The center-to-edge temperature differential may be compared a predetermined center-to-edge temperature differential and the laser illumination when the center-to-edge differential is greater than the predetermined center-to-edge temperature differential.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system including a chamber arrangement in accordance with the present disclosure, schematically showing the chamber arrangement supporting a substrate during deposition of material layer onto the substrate;

FIG. 2 is a schematic view of the semiconductor processing system of FIG. 1 according to an example, schematically showing a precursor delivery arrangement providing a material layer precursor to the chamber arrangement during deposition of the material layer;

FIGS. 3 and 4 are cross-sectional and plan views of the chamber arrangement of FIG. 1 according to an example, schematically showing a laser source optically coupled to the substrate along a lasing axis during deposition of the material layer onto the substrate;

FIGS. 5-7 are cross-sectional and exploded views of a portion of the chamber arrangement of FIG. 1 including the laser source according to an example of the present disclosure, showing a lens element optically coupling the laser source to an edge portion of the substrate to heat the edge portion of substrate during deposition of the material layer onto the substrate;

FIG. 8 is chart of material layer thickness deposited onto substrates with and without using the laser source to heat an outer periphery of the substrate, showing edge roll-up in material layer at the peripheral portion of a substrate with and without laser illumination;

FIGS. 9 and 10 are cross-sectional plan views of the chamber arrangement of FIG. 1 according to an example, showing the laser source being controlled using a thermocouple fixed relative to a substrate support supported for rotation within the chamber arrangement;

FIGS. 11 and 12 are cross-sectional plan views of the chamber arrangement of FIG. 1 according to an example, showing the laser source being controlled using a thermocouple fixed relative to the chamber body during deposition of the material layer onto the substrate;

FIGS. 13 and 14 are cross-sectional plan views of the chamber arrangement of FIG. 1 according to an example of the present disclosure, showing the laser source being controlled using a substrate surface temperature measurement provided by a pyrometer optically coupled to the substrate during deposition of the material layer onto the substrate;

FIGS. 15 and 16 are cross-sectional plan views of the chamber arrangement of FIG. 1 according to another example of the present disclosure, showing the laser source being controlled according to substrate surface temperature variation determined using two pyrometers optically coupled to the substrate during deposition of the material layer onto the substrate;

FIGS. 17 and 18 are cross-sectional plan views of the chamber arrangement of FIG. 1 according to a further example of the present disclosure, showing the laser source being controlled according to substrate surface temperature gradient determined using three pyrometers optically coupled to the substrate during deposition of the material layer onto the substrate; and

FIG. 19-22 are block diagrams of material layer depositions method according to an example of the present, showing operations of the methods according to illustrative and non-limiting examples of the material layer deposition methods.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

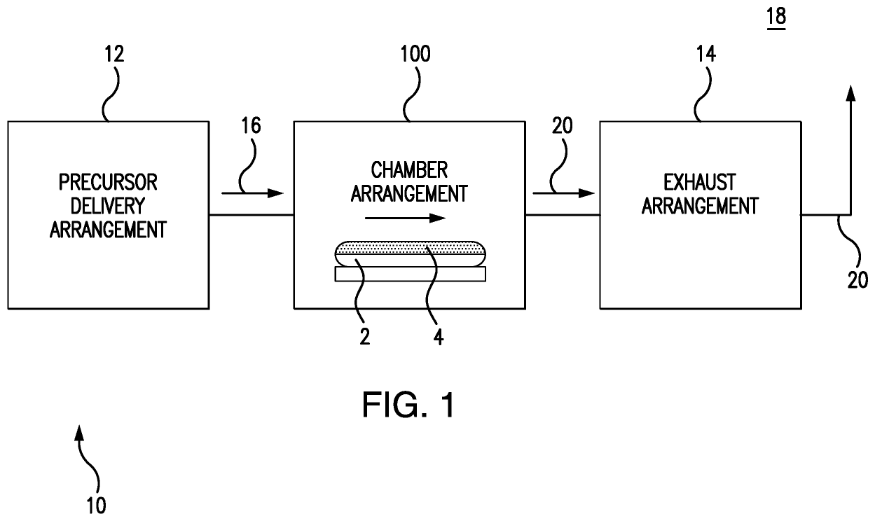

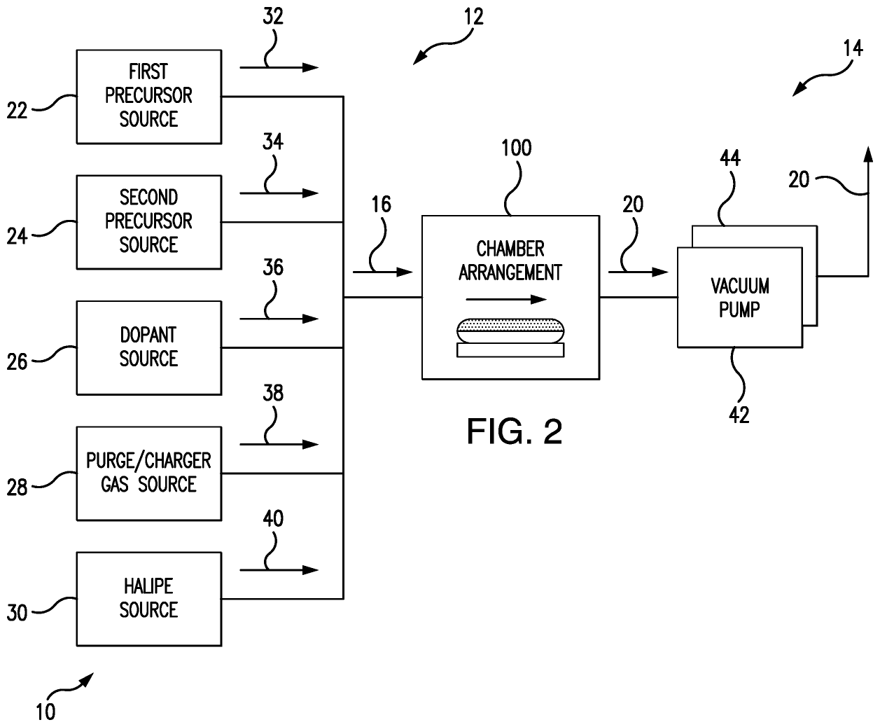

Reference will now be made to the drawings wherein like reference numerals identify similar structural features or aspects of the subject disclosure. For purposes of explanation and illustration, and not limitation, a partial view of an example of a chamber arrangement in accordance with the present disclosure is shown in FIG. 1 and is designated generally by reference character 100. Other examples of chamber arrangements, semiconductor processing systems, and methods of depositing material layers onto substrates in accordance with the present disclosure, or aspects thereof, are provided in FIGS. 2-22, as will be described. The systems and methods of the present disclosure can be used to control temperature of the peripheral portion of substrates during the deposition of material layers onto the substrates, such as during the deposition of epitaxial material layers onto patterned substrates where the material layer may exhibit a roll-up or roll-down profile due edge emissivity, however the present disclosure is not limited to patterned substrates or to epitaxial material deposition techniques in general.

With reference to FIG. 1, a semiconductor processing system 10 is shown. The semiconductor processing system 10 includes a precursor delivery arrangement 12, the chamber arrangement 100, and an exhaust arrangement 14. The precursor delivery arrangement 12 is connected to the chamber arrangement 100 and is configured to provide a material layer precursor 16 to the chamber arrangement 100. The chamber arrangement 100 is connected to the exhaust arrangement 14 and is configured to deposit a material layer 4 onto a substrate 2 supported within the chamber arrangement 100 using the material layer precursor 16. The exhaust arrangement 14 is in fluid communication with the environment 18 external to the semiconductor processing system 10 and is configured to communicate a flow of residual precursor and/or reaction products 20 to the environment 18 external to the semiconductor processing system 10.

As used herein, the term “substrate” may refer to any underlying material or materials that may be used, or upon which, a device, a circuit, or a film may be formed. The “substrate” may be continues or non-continuous; rigid or flexible; solid or porous. The substrate may be in any form such as a powder, a plate, or a workpiece. Substrates in the form of a plate may include wafers, e.g., 300-millimeter silicon wafers, in various shapes and sizes. Substrates may be made from materials such as silicon, silicon germanium, silicon oxide, gallium arsenide, gallium nitride and silicon carbide by way of non-limiting example. Substrates may include a pattern or may be not have a pattern, such blanket-type substrates. A continuous substrate may extend beyond the bounds of a process chamber where a deposition process occurs and may move through the process chamber such that the process continues until the end of the substrate is reached. A continuous substrate may be supplied from a continuous substrate feeding system, enabling manufacture and output of the continuous substrate in any appropriate form.

With reference to FIG. 2, the precursor delivery arrangement 12 and the exhaust arrangement 14 are shown. The precursor delivery arrangement 12 includes a first precursor source 22, a second precursor source 24, and a dopant source 26. The precursor delivery arrangement 12 also includes a purge/carrier gas source 28 and a halide source 30. The first precursor source 22 is connected to the chamber arrangement 100, includes a silicon-containing precursor 32, and is configured to provide a flow of the silicon-containing precursor 32 to the chamber arrangement 100. Examples of suitable silicon-containing precursors include chlorinated silicon-containing precursors, such as dichlorosilane (H₂SiCl₂) and trichlorosilane (HCl₃Si), and non-chlorinated silicon-containing precursors, such as silane (SiH₄) and disilane (Si₂H₆).

The second precursor source 24 is connected to the chamber arrangement 100, includes a germanium-containing precursor 34, and is configured to provide a flow of the germanium-containing precursor 34 to the chamber arrangement 100. Examples of suitable germanium-containing precursors include germane (GeH₄). The dopant source 26 is similarly connected to the chamber arrangement 100, includes a dopant-containing precursor 36, and is further configured to provide a flow to the dopant-containing precursor 36 to the chamber arrangement 100. The dopant-containing precursor 36 may include an n-type dopant. The dopant-containing precursor 36 may include a p-type dopant. The In certain examples the dopant-containing precursor 36 may include phosphorous (P). It is also contemplated that the dopant-containing precursor 36 may include boron (B) and/or arsenic (As) and remain within the scope of the present disclosure.

The purge/carrier gas source 28 is further connected to the chamber arrangement 100, includes a purge/carrier gas 38, and is additionally configured to provide a flow of the purge/carrier gas 38 to the chamber arrangement 100. In this respect the purge/carrier gas source 28 may be configured to employ the purge/carrier gas 38 to carry one or more of the silicon-containing precursor 32, the germanium-containing precursor 34, and/or the dopant-containing precursor 36 into the chamber arrangement 100. Examples of suitable purge/carrier gases include hydrogen (H₂) gas, inert gases such as nitrogen (N₂) gas, argon (Ar) or helium (He) gas, and mixtures thereof.

The halide source 30 is connected to the chamber arrangement 100, includes a halide-containing material 40, and is configured to provide a flow of the halide-containing material 40 to the chamber arrangement 100. The halide-containing material 40 may be co-flowed with the material layer precursor 16. The halide-containing material 40 may be flowed independently from the material layer precursor 16, such as to provide a purge and/or to remove condensate from within the chamber arrangement 100. Examples of suitable halides include chlorine (Cl), such as chlorine (Cl₂) gas and hydrochloric (HCl) acid, as well as fluorine (F), such fluorine (F₂) gas and hydrofluoric (Hf) acid.

The exhaust arrangement 14 is configured to evacuate the chamber arrangement 100 and in this respect may include one or more vacuum pump 42 and/or an abatement apparatus 44. The one or more vacuum pump 42 may be connected to the chamber arrangement 100 and configured to control pressure within the chamber arrangement 100. The abatement apparatus 44 may be connected to the one or more vacuum pump 42 and configured to process the flow a residual precursor and/or reaction products 20 issued by the chamber arrangement 100. It is contemplated that the exhaust arrangement 14 may be configured to maintain environmental conditions within the chamber arrangement 100 suitable for atmospheric deposition operations, such as pressures between about 500 torr and about 760 torr, such as during the deposition of epitaxial material layers including silicon during atmospheric pressure techniques. The exhaust arrangement 14 may also be configured to maintain environmental conditions within the exhaust arrangement 14 suitable for reduced pressure deposition operations, such as pressures between about 3 torr and about 500 torr, such as during the deposition of epitaxial material layers including using reduced pressure techniques.

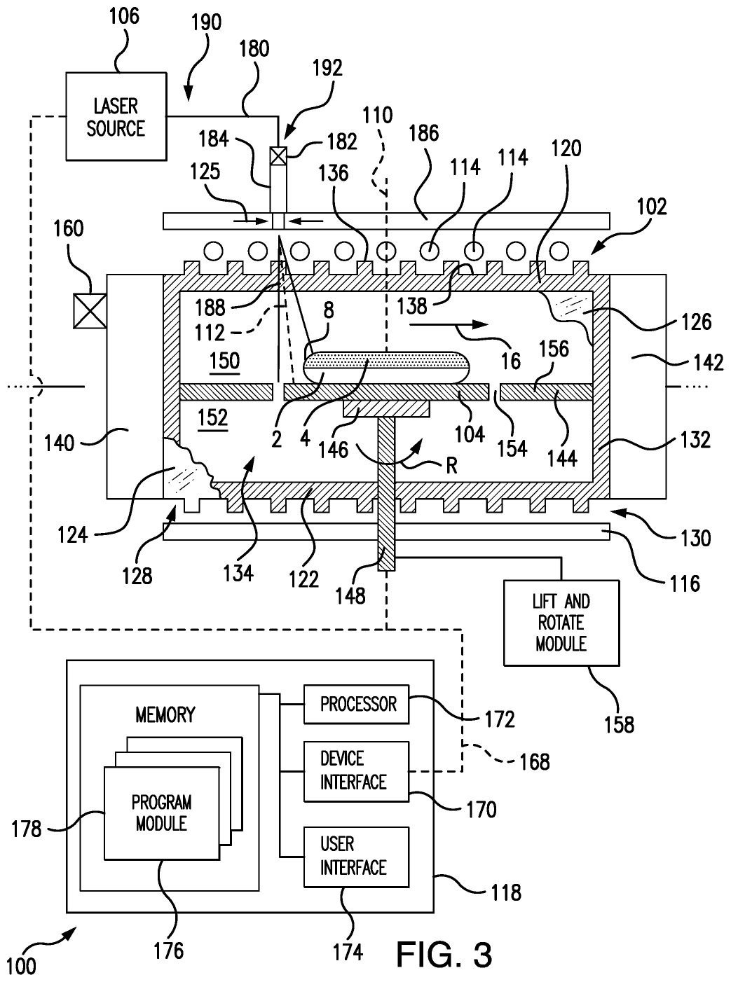

With reference to FIG. 3, the chamber arrangement 100 is shown. The chamber arrangement 100 includes a chamber body 102, a substrate support 104, and a laser source 106. The substrate support 104 is arranged within an interior 134 of the chamber body 102 and is supported for rotation R about a rotation axis 110 (e.g., rotatably supported) relative to the chamber body 102. The laser source 106 is arranged outside of the chamber body 102 and is optically couped to the substrate support 104 along a lasing axis 112. It is contemplated that the lasing axis 112 intersect the substrate support 104 at a location radially outward from a bevel or edge 8 of the substrate 2 while the substrate 2 is seated on an upper surface of the substrate support 104. In the illustrated example the chamber arrangement 100 also includes an upper heater element array 114, a lower heater element array 116, and a controller 118. Although the chamber arrangement 100 is shown and described herein as having a specific arrangement, it is to be understood and appreciated that the chamber arrangement 100 may have a different arrangement in other examples and remain within the scope of the present disclosure.

The chamber body 102 is configured to flow the material layer precursor 16 across the substrate 2 during deposition of the material layer 4 onto the substrate 2 and has an upper wall 120, a lower wall 122, a first sidewall 124, and a second sidewall 126. The upper wall 120 of the chamber body 102 extends longitudinally between an injection end 128 and a longitudinally opposite exhaust end 130 of the chamber body 102, is supported horizontally relative to gravity, is formed from a transmissive material 132. The lower wall 122 is similar to the upper wall 120 and is additionally spaced apart from the upper wall 120 by an interior 134 of the chamber body 102. The first sidewall 124 extends between the injection end 128 and the exhaust end 130 of the chamber body 102, connects the upper wall 120 of the chamber body 102 and the lower wall 122 of the chamber body 102, and may also be formed from the transmissive material 132. The second sidewall 126 is similar to the first sidewall 124 and is additionally spaced apart from the first sidewall 124 by the interior 134 of the chamber body 102. In certain examples, the chamber body 102 may have a plurality of external ribs 136 extending about an exterior surface 138 of the chamber body 102. In accordance with certain examples, one or more of the walls 120-126 may be substantially planar. It is also contemplated that the chamber body 102 may have no ribs and/or define an arcuate or dome-like wall and remain within the scope of the present disclosure.

The chamber arrangement 100 may further include an injection flange 140 and an exhaust flange 142. The injection flange 140 may abut the injection end 128 of the chamber body 102 and fluidly couple the precursor delivery arrangement 12 (shown in FIG. 1) to the interior 134 of the chamber body 102. The exhaust flange 142 may abut the exhaust end 130 of the chamber body 102 and fluidly couple the exhaust arrangement 14 (shown in FIG. 1) to the interior 134 of the chamber body 102.

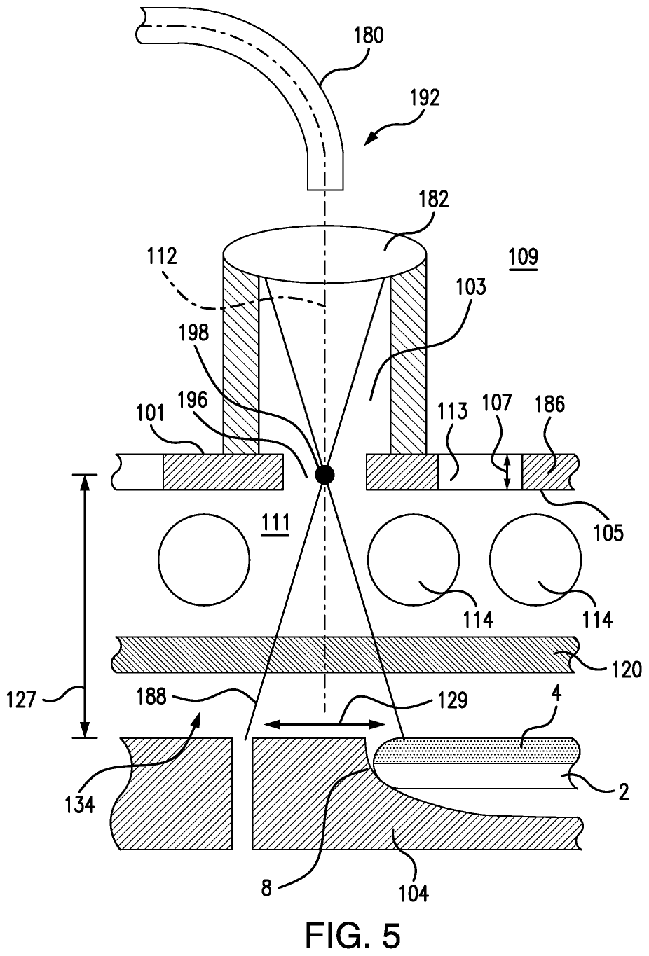

The chamber arrangement 100 may additionally include a divider 144, a support member 146, and a shaft member 148. The divider 144 may be fixed within the interior 134 of the chamber body 102, divide the interior 134 of the chamber body 102 into an upper chamber 150 and a lower chamber 152, and define divider aperture 154 therethrough. The divider aperture 154 may be circular in shape and fluidly couple the upper chamber 150 of the chamber body 102 to the lower chamber 152 of the chamber body 102. The substrate support 104 may be arranged within the divider aperture 154 and configured to support the substrate 2 during deposition of the material layer 4 onto the upper surface 6 of the substrate 2. In certain examples, the substrate support 104 may be configured to provide edge support at the bevel or edge 8 (shown in FIG. 5) of the substrate 2, a center portion of the substrate 2 in such examples being offset from an upper surface of the substrate support 104 along the rotation axis 110. In accordance with certain examples, the substrate support 104 and the divider 144 may be formed from an opaque material 156, such as graphite or silicon carbide. Examples of suitable substate supports include those shown and described in U.S. Pat. No. 7,070,660 B2 to Keeton et al, issued on Jul. 4, 2006, the contents of which is incorporated herein by reference.

The support member 146 may be arranged along the rotation axis 110, fixed in rotation relative to the substrate support 104, and arranged within the lower chamber 152 of the chamber body 102. The shaft member 148 may be fixed in rotation relative to the support member 146, extend along the rotation axis 110 and through the lower wall 122 of the chamber body 102, and operably connect a lift and rotate module 158 to the substrate support 104 through the support member 146. The lift and rotate module 158 may be configured to rotate the substrate support 104 about the rotation axis 110. The lift and rotate module 158 may further be configured seat and unseat the substrate 2 from the substrate support 104 and in this respect may cooperate with a lift pin arrangement located within the interior 134 of the chamber body 102. The lift and rotate module 158 may further cooperate with a gate valve 160 to load and unload the substrate 2 the interior 134 of the chamber body 102, the gate valve 160 in turn interfacing the chamber arrangement 100 to the external environment outside of the chamber body 102, for example, through a cluster-type platform arrangement.

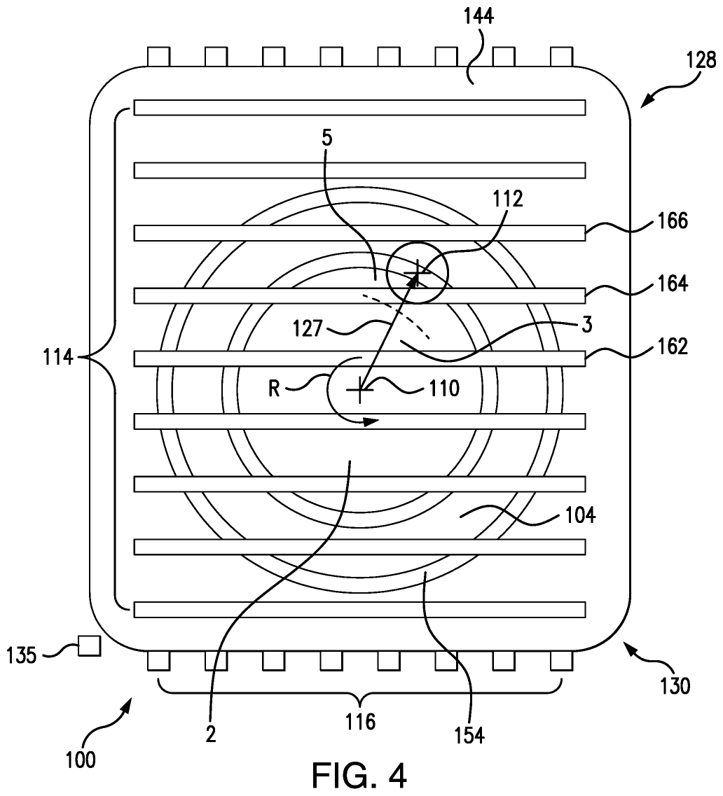

With reference to FIG. 4, the upper heater element array 114 is supported above the chamber body 102 and includes a plurality of upper heater elements. In this respect it is contemplated that the upper heater element array 114 include a first upper heater element 162, a second upper heater element 164, and at least one third upper heater element 166. The first upper heater element 162 may include a linear filament supported within a quartz tube. The first upper heater element 162 may by further extend laterally above the upper wall 120 (shown in FIG. 3) of the chamber body 102 (shown in FIG. 3) between the first sidewall 124 (shown in FIG. 3) and the second sidewall 126 (shown in FIG. 3) of the chamber body 102.

The second upper heater element 164 is similar to the first upper heater element 162 and additionally extends in parallel with the first upper heater element 162 with the first upper heater element 162. The second upper heater element 164 is further longitudinally spaced apart from the first upper heater element 162 between the injection end 128 and the exhaust end 130 of the chamber body 102. The third upper heater element 166 may also be similar to the first upper heater element 162, extend in parallel with the first upper heater element 162, and be longitudinally offset from the from the first upper heater element 162 and the second upper heater element 164.

The second upper heater element 164 may be arranged longitudinally between the first upper heater element 162 and the lasing axis 112. The lasing axis 112 may be longitudinally between the second upper heater element 164 and the at least one third upper heater element 166. In certain examples the upper heater element array 114 may include twelve (12) linear heater elements. In accordance with certain examples, the plurality of upper heater elements of the upper heater element array 114 may extend longitudinally between the injection end 128 and the exhaust end 130 of the chamber body 102. The plurality of upper heater elements may be laterally spaced apart from the one another between the first sidewall 124 and the second sidewall 126 of the chamber body 102 examples. It is also contemplated that, in accordance with certain examples, the upper heater element array 114 may include (e.g., consist of) a plurality of bulb or lamp elements, or a different number of linear heater elements than shown and described herein, and remain within the scope of the present disclosure.

The lower heater element array 116 is similar to the upper heater element array 114 and is additionally supported below the lower wall 122 (shown in FIG. 3) of the chamber body 102 (shown in FIG. 3). In this respect the lower heater element array 116 may include a plurality of lower heater elements. Each of the lower heater element may include a linear filament arranged within a quartz tube and configured to communicate heat into the interior 134 of the chamber body 102 through the lower wall 122 of the chamber body 102. The lower heater elements may each extend longitudinally between the injection end 128 and the exhaust end 130 of the chamber body 102, be laterally spaced apart from one another, and be orthogonal to the plurality of upper heater elements of the upper heater element array 114. In certain examples, the lower heater element array 116 may include twelve (12) lower heater elements. In accordance with certain examples, the lower heater element array 116 may include one or more bulb or lamp elements. It is also contemplated that the plurality of lower heart elements may extend laterally between the first sidewall 124 (shown in FIG. 3) and the second sidewall 126 (shown in FIG. 3) of the chamber body 102 and remain within the scope of the present disclosure.

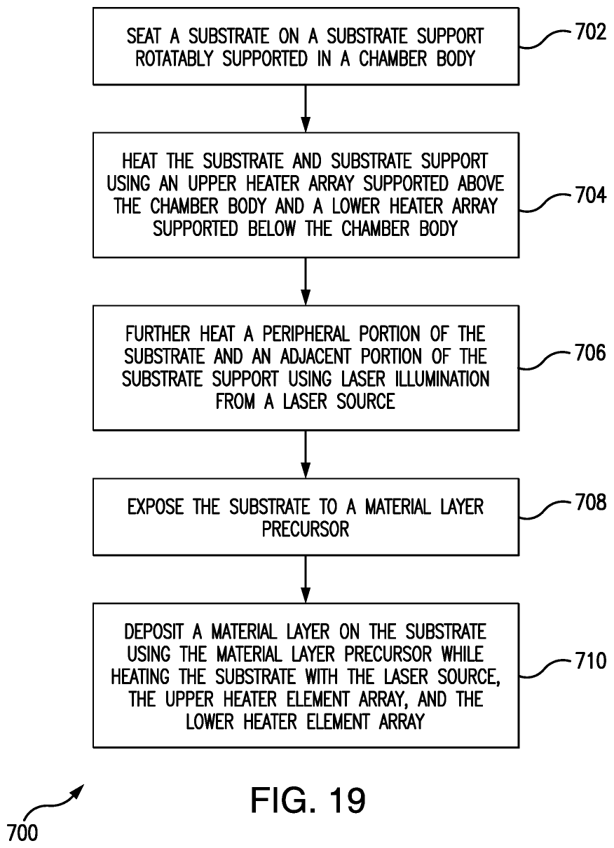

With continuing reference to FIG. 3, the controller 118 may be operatively connected to the laser source 106 by a wired or wireless link 168 and in this respect may include a device interface 170, a processor 172, a user interface 174, and a memory 176. The device interface 170 may connect the processor 172 to the wired or wireless link 168, and therethrough to the laser source 106. The processor 172 may be operatively connected to the user interface 174 to receive user input and/or provide user output therethrough, and may be further disposed in communication with the memory 176. The memory 176 may include a non-transitory machine-readable medium having a plurality of program modules 178 recorded thereon containing instruction that, when read by the processor 172, cause the processor 172 to execute certain operations. Among the operations may be operations of a material layer deposition method 800 (shown in FIG. 19), as will be described. Although shown and described herein as having a specific arrangement it is to be understood and appreciated that the controller 118 may have different arrangements in other examples of the present disclosure, such as a distributed architecture, and remain within the scope of the present disclosure.

The laser source 106 may be optically coupled to the interior 134 of the chamber body 102. In this respect the laser source 106 may be optically coupled by a waveguide 180 and therethrough by the one or more lens element 182, a mount 184, and a reflector body 186 to the interior 134 of the chamber body 102. The waveguide 180 may have an input end 190 and an output end 192. The input end 190 may be connected to the laser source 106. The output end 192 may be connected to the one or more lens element 182 and/or the mount 184. An optical fiber extending between the input end 190 and output end 192 of the waveguide.

The laser source 106 may be configured to provide the laser illumination 188 in a waveband transmissive to the chamber body 102. In certain examples, the waveband may be less than 50 nanometers, or less than 30 nanometers, or even less than about 20 nanometers. In accordance with certain examples, the laser source 106 may be configured to provide the laser illumination within a waveband having a center wavelength that is between about 800 nanometers and about 850 nanometers, or that is between about 800 nanometers and about 830 nanometers, or that is even between about 800 nanometers and about 810 nanometers. In further examples, the laser source 106 may have an output power that is between about 150 watts and about 220 watts, or between about 155 watts and about 200 watts, or between about 160 watts and about 190 watts. Laser sources having wavebands, center wavelengths, and power levels within these ranges may be able to impart sufficient heat to the peripheral portion and substate support surface radially outward therefrom to limit thickness variation of a material layer deposited thereon such that semiconductor devices fabricated within the peripheral portion a substrate to exhibit performance characteristics similar to semiconductor devices formed within the central portion of the substrate. As will be appreciated by those of skill in the art in view of the present disclosure, this can reduce (or eliminate) the tendency of edge die to not yield during the fabrication of certain semiconductor devices. Examples of suitable laser sources include IS10-SMA laser, available from Coherent Incorporated of Santa Clara, California.

The lasing axis 112 may be radially outward of the substrate 2. For example, the substrate 2 may include a 300-millimeter wafer, and lasing axis 112 may interest the substrate support 104 at a radial offset 131 from the rotation axis 110 that is between about 150 millimeters and about 200 millimeters, or is between about 151 millimeters and about 170 millimeters, or is even between about 151 millimeters and about 155 millimeters. The radial offset 131 between the rotation axis 110 and the lasing axis at the substrate support may be about 152 millimeters. Advantageously, radial offsets within this range allow the laser source 106 to heat both a radially outer portion of the substrate 2 and a portion of the substrate support 104 abutting the substrate, limiting (or eliminating) heat flux at the interface between the bevel or edge 8 of the substrate 2 and the substrate support 104. To further advantage, radial offsets that nominally cause more of the laser illumination 188 to be incident on the substrate support 104 than on the substrate 2 accommodate variation in position of the substrate 2 on the substrate support 104, for example, due to tolerance stack-up in the lift and rotate module 158 and/or the lift pin arrangement employed to seat substrates on the substrate support 104.

With reference to FIG. 5, the one or more lens element 182 may be arranged along the lasing axis 112 and optically coupled the laser source 106 to both the substrate support 104 and the substrate 2 through the upper wall 120 of the chamber body 102. In this respect the one or more lens element 182 may be optically coupled to the substrate support 104 and the substrate 2 through the mount 184, for example, through a bore 103 extending through the mount 184 and about the lasing axis 112. The one or more lens element 182 may be further optically coupled to the substrate support 104 and the substrate 2 by the reflector body 186, for example, through a lasing aperture 196 defined by the reflector body 186 and extending about the lasing axis 112. The lasing aperture 196 may have a rounded shape, such as an elliptical or a circular shape.

In certain examples, the one or more lens element 182 may include a diverging lens element. In accordance with certain examples, the one or more lens element 182 may include a converging lens element. It is contemplated that, in accordance with certain examples, the one or more lens element 182 may define a focal point 198. The focal point 198 may be located outside the chamber body 102, for example, within the lasing aperture 196 of the reflector body 186. Advantageously, locating the focal point 198 within the lasing aperture 196 can simplify the chamber arrangement 100, for example, by allowing shape of the lasing aperture 196 to define shape of the lasing spot 194 within the interior 134 of the chamber body 102.

The mount 184 may support the one or more lens element 182 above the reflector body 186 and register the one or more lens element 182 to the lasing aperture 196. In this respect the one or more lens element 182 may be seated on the mount 184, for example, on an end of the mount 184 opposite the chamber body 102. The mount 184 may be arranged along the lasing axis 112 and be fixed to a mounting surface 101 of the reflector body 186. The mount 184 may further define a bore 103 extending therethrough. The bore 103 may extend along and about the lasing axis 112, the bore 103 (and thereby the mount 184) optically coupling the laser source 106 (shown in FIG. 3) to the interior 134 of the chamber body 102 through the one or more lens element 182 and the lasing aperture 196. In certain examples, the mount 184 may have a vertical height substantially equivalent to a focal length of the one or more lens element 182. As will be appreciated by those of skill in the art in view of the present disclosure, forming the mount 184 with a height substantially equivalent to the focal length of the one or more lens element 182 positions the focal point 198 of the one or more lens element 182 within the lasing aperture 196, limiting width of the beam between the upper heater elements of the upper heater element array 114 without limit size of the lasing spot 194 incident upon the substrate 2 and upper surface of the substrate support 104.

The reflector body 186 may be supported above the chamber body 102 and define therethrough the lasing aperture 196. The lasing aperture 196 may extend about the lasing axis 112, the lasing axis 112 extending through the lasing aperture 196, the reflector body 186 (via the lasing aperture 196) thereby optically coupling the laser source 106 (shown in FIG. 3) to the interior 134 of the chamber body 102. In this respect the reflector body 186 may be supported above the upper heater element array 114 and have a reflective surface 105 separated from a mounting surface 101 by a thickness 107 of the reflector body 186. The reflective surface 105 may oppose the upper wall 120 of the chamber body 102 and has a reflective coating, such as a gold coating. The thickness 107 of the reflector body 186 is formed from a metallic material, such as brass, and spaces the mounting surface 101 from the reflective surface 105. The mounting surface 101 may be opposite the reflective surface 105 and configured to seat the mount 184.

The reflector body 186 separate a coolant source plenum 109 from a coolant supply plenum 111. In this respect the mounting surface 101 of the reflector body 186 may bound the coolant source plenum 109 and the reflective surface 105 of the reflector body 186 may bound the coolant supply plenum 111. The reflector body 186 may define a coolant slot 113 therethrough extending between the mounting surface 101 and reflective surface 105, the coolant slot 113 fluidly coupling the coolant source plenum 109 to the coolant supply plenum 111. It is also contemplated that the chamber body 102 be cooled by flowing coolant received within the coolant source plenum 109 through the coolant slot 113 to the coolant supply plenum 111, the coolant thereby flowing across the exterior surface 138 of the chamber body 102 to cool the chamber body 102, the chamber arrangement 100 (shown in FIG. 1) being a cold wall chamber arrangement. In further respect, coolant flow may be according to a chamber pyrometer supported by the reflector body 186 and optically coupled the upper wall 120 of the chamber body 102 to acquire wall temperature from the chamber body 102 during deposition of the material layer 4 onto the substrate 2.

The lasing aperture 196 may have a lasing aperture width 125 (shown in FIG. 3) and vertically spaced from the substrate support 104 and the peripheral portion 5 of the substrate 2 by a lasing aperture height 127. The lasing aperture 196 may also define a lasing spot 194 having lasing spot width 129 at the substrate 2 and the substrate support 104. The lasing aperture width 125 may be a diameter. The lasing spot width 129 may be between about 10 millimeters and about 40 millimeters, or between about 10 millimeters and about 30 millimeters, or even between about 10 millimeters and about 20 millimeters. In certain examples, the lasing spot width 129 may be about 20 millimeters. Lasing spot widths within these ranges enable illumination of the peripheral portion 5 of the substrate 2 using the laser illumination 188 with sufficient radial extent to limit edge roll-up or edge roll-down in the material layer 4 deposited onto the substrate 2 while illuminating a surface portion of the substrate support 104 radially outward of the substrate 2 sufficient to limit (or eliminate) heat flux between the substrate 2 and the substrate support 104. As will be appreciated by those of skill in the art in view of the present disclosure, limiting (or eliminating) heat flux between the substrate 2 and the substrate support 104 enables controlling temperature of the substrate 2 at radial locations where temperature is not directly measured.

The lasing aperture width 125 may be between about 5 millimeters and about 45 millimeters, or between about 5 millimeters and about 30 millimeters, or even between about 5 millimeters and about 15 millimeters. For example, the lasing aperture 196 may have a lasing aperture width 125 that is about 6.5 millimeters. The lasing aperture height 127 may be between about 50 millimeters and about 175 millimeters, or between about 75 millimeters and about 150 millimeters, or even between about 80 millimeters and about 125 millimeters. For example, the lasing aperture height 127 may be about 100 millimeters. Lasing aperture widths and lasing aperture heights within these ranges prevents the upper heater element pair adjacent to the lasing aperture 196 from blocking the laser illumination 188, limiting (or eliminating) the tendency of the laser illumination 188 to heat the upper heater elements, potentially reducing reliability of the chamber arrangement 100 by accelerating aging of the upper heater elements adjacent to the lasing aperture 196.

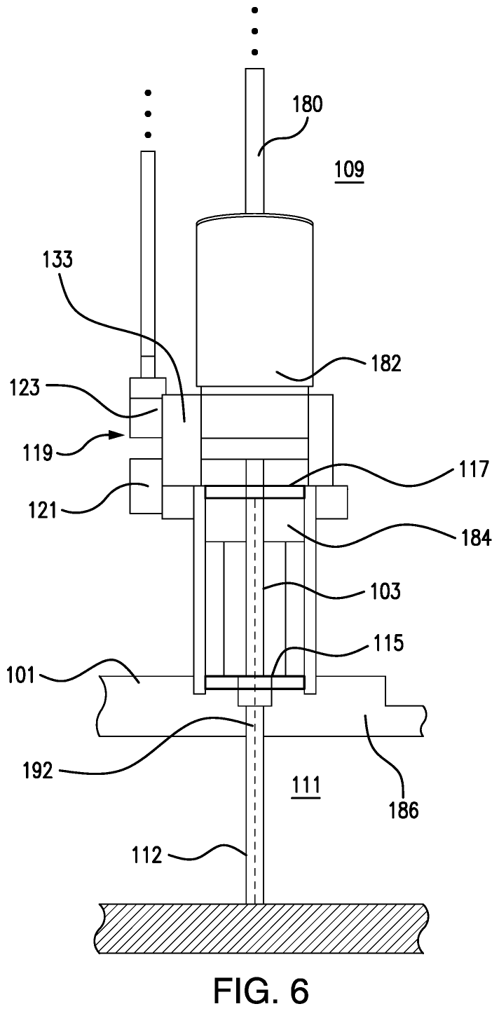

With reference FIG. 6, the mount 184 may be fluidly separate the coolant source plenum 109 from the coolant supply plenum 111. In this respect a first sealing member 115 may be arranged between the mount 184 and the reflector body 186, and a second sealing member 117 may be arranged above the first sealing member 115 and between the mount one or more lens element 182. The first sealing member 115 may extend about the lasing axis 112 and be compressively seated between the mount 184 and the mounting surface 101 of the reflector body 186 to fluidly separate the bore 103 from the coolant source plenum 109. The second sealing member 117 may be compressively seated between the mount 184 and the one or more lens element 182 (or a lens element housing) to fluidly separate the bore 103 from the coolant source plenum 109. The bore 103 may be fluidly coupled to the coolant supply plenum 111 through the coolant supply plenum 111 and the coolant slot 113, the first sealing member 115 and the second sealing member 117 rendering flow within the bore 103 substantially static. Advantageously, sealing the bore 103 from the coolant source plenum 109 limits interruption to coolant flow through the coolant slot 113, limiting (or eliminating) interruption of coolant distribution by the coolant slot 113 across the upper wall 120 of the chamber body 102 while avoiding transmission loss otherwise associated with positioning a lasing winding in the lasing aperture 196. In certain examples, the first sealing member 115 may include a gasket or an O-ring. In accordance with certain examples, the second sealing member 117 may include a gasket or O-ring. It is also contemplated that, in accordance with certain examples, both the first sealing member 115 and the second sealing member 117 may include a gasket or O-ring.

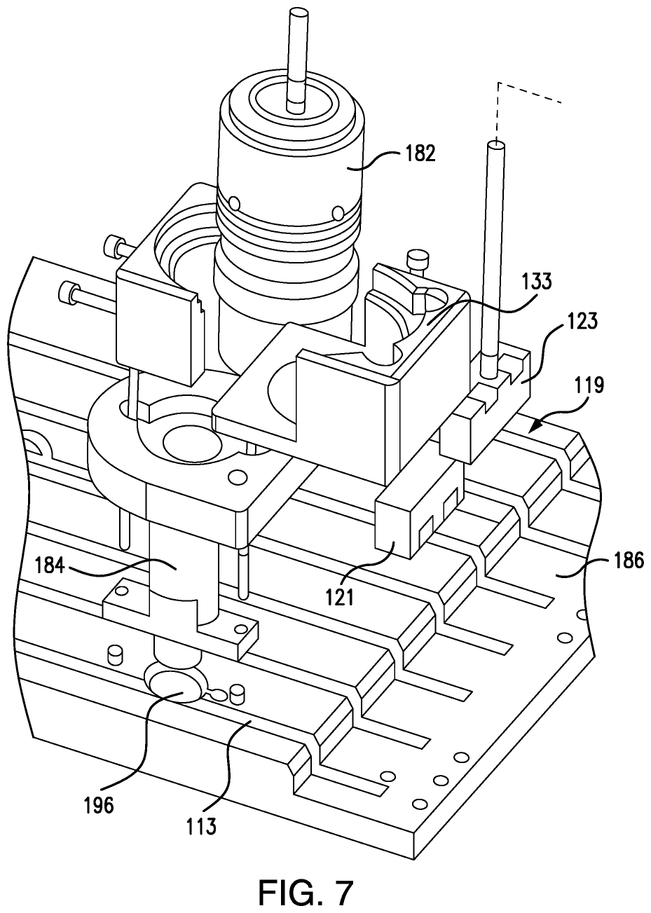

With reference to FIG. 7 and continuing reference to FIG. 6, an interlock switch 119 may be connected to the mount 184 and/or the one or more lens element 182. The interlock switch 119 may be operably connected to the laser source 106 (shown in FIG. 3) to remove power from the laser source 106 when the one or more lens element 182 is removed from the mount 184, for example, during maintenance or service of the chamber arrangement 100. Operable connection may be through the controller 118 (shown in FIG. 3) via the wired or wireless link 168 (shown in FIG. 3), the controller 118 in turn configured to remove power to the laser source 106 when the interlock switch 119 provides an indication that the one or more lens element 182 has been removed from the mount 184. As will be appreciated by those of skill in the art in view of the present disclosure, removing power from the laser source 106 when the one or more lens element 182 is separated from the mount 184 may limit (or eliminate) risk that personnel servicing the chamber arrangement 100 are exposed to the laser illumination 188 during service and/or maintenance, limiting (or eliminating risk of injury) otherwise attendant with such service and/or maintenance events.

The interlock switch 119 may have a mount portion 121 and a lens portion 123. The mount portion 121 may be fixed relative to the mount 184, the lens portion 123 may be fixed relative to the one or more lens element 182, and the mount portion 121 and the lens portion 123 electromagnetically coupled the mount portion 121 when proximate (e.g., abutting) one another. The lens portion 123 may be further connected to the controller 118 and configured to provide a signal to the controller 118 when the electromagnetic coupling between the lens portion 123 and the mount portion 121 is interrupted. As will be appreciated by those of skill in the art in view of the present disclosure, fixation of the lens portion 123 relative to the one or more lens element 182 and the mount portion 121 to the mount 184 may errorproof interlock of the laser source 106 (shown in FIG. 3) to position of the one or more lens element 182, avoiding the need to employ lockout-tagout protocols during service of the one or more lens element 182, e.g., during cleaning of the one or more lens element 182, reducing green-to-green time associated with such cleaning events. In certain examples, the lens portion 123 may be coupled to the one or more lens element 182 by a locating plate 133, the locating plate 133 fixing the one or more lens element 182 to the mount 184 to error-proof position of the one or lens element 182 relative to the mount 184 and therethrough the lasing aperture 196. As will be appreciated by those of skill in the art in view of the present disclosure, error-proofing position of one or more lens element 182 can simplify service and/or maintenance of the chamber arrangement 100, for example by eliminating the need to collimate the one or more lens element 182 to the chamber body 102 subsequent to removal and replacement for cleaning, limiting green-to-green time associated with cleaning events.

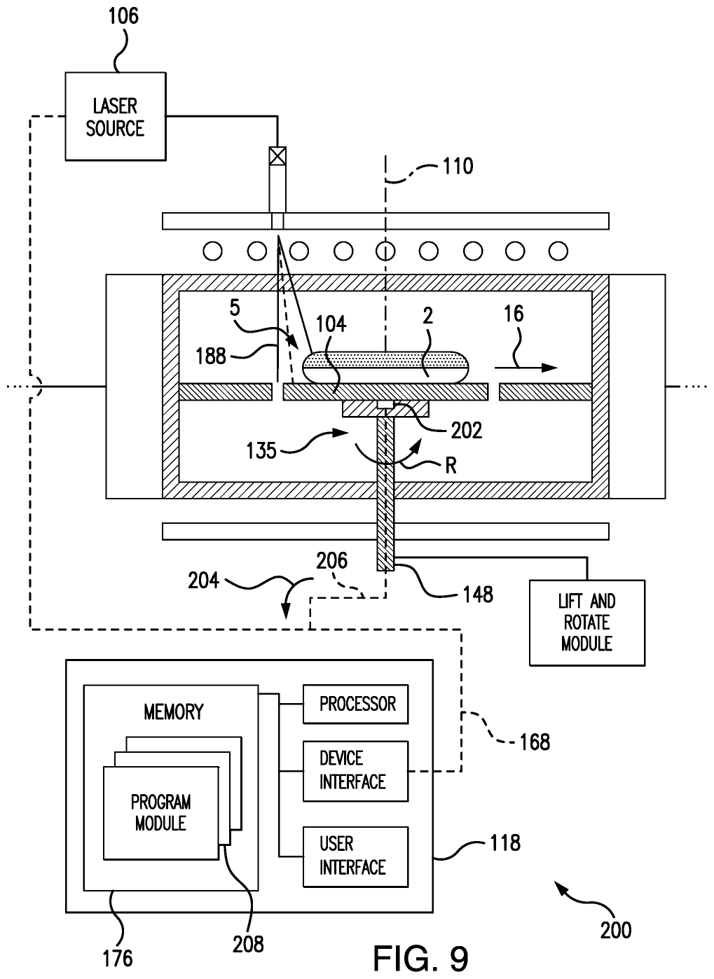

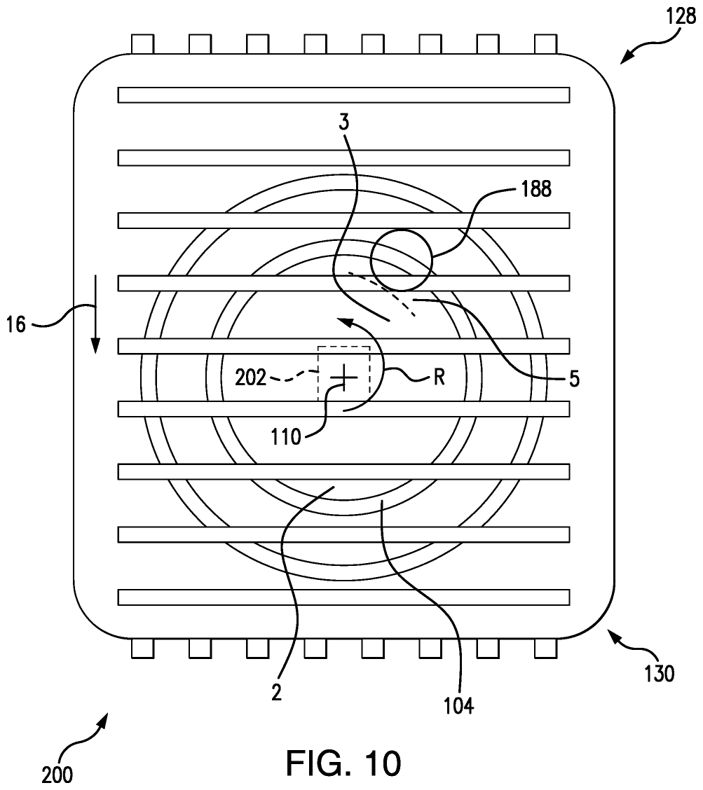

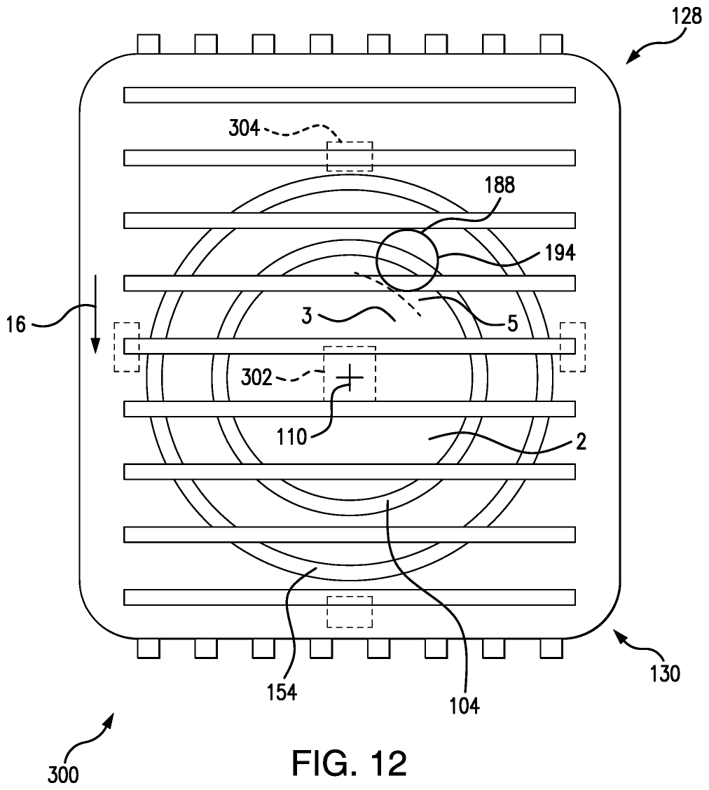

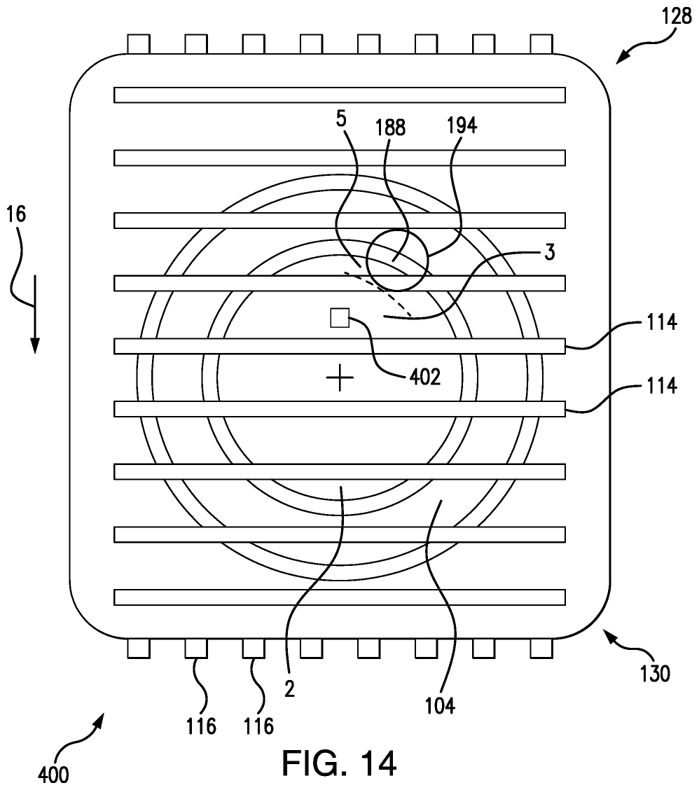

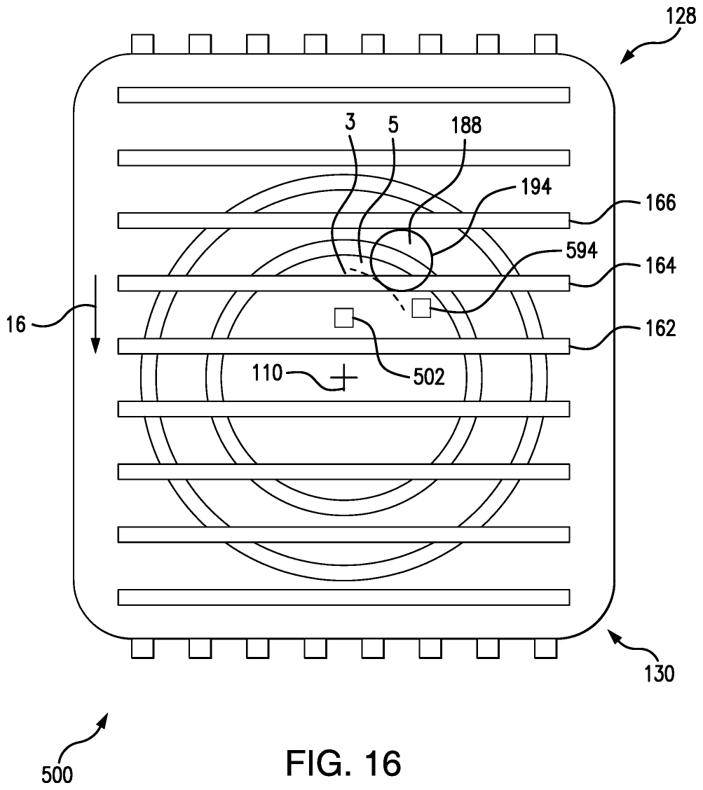

With continuing reference to FIG. 4, the chamber arrangement 100 may include a temperature sensor 135. The temperature sensor 135 may be operably connected to the laser source 106, for example through the controller 118 and the wired or wireless link 168, to control heating of the substrate 2 and the substrate support 104 using the laser illumination 188 based using a temperature measurement 137 acquired by the temperature sensor 135. In certain examples, the temperature sensor 135 may include a thermocouple, such as a rotating thermocouple 202 (shown in FIG. 9) and/or a static thermocouple 304 (shown in FIG. 10) to throttle (and thereby control) the laser illumination 188 provided by the laser source 106. In accordance with certain examples, the temperature sensor 135 may include a pyrometer to throttle the laser illumination 188 provided by the laser source 106. In this respect the temperature sensor 135 may include a pyrometer 402 (shown in FIG. 12) or a center pyrometer 502 (shown in FIG. 14) and an edge pyrometer 504 (shown in FIG. 14). In further respect, the temperature sensor 135 may include a middle pyrometer 606 (shown in FIG. 16) to throttle the laser illumination 188 provided by the laser source 106. Although shown and described herein as including thermocouples and/or pyrometers, it is to be understood and appreciated that the temperature sensor 135 may include other types of temperature sensors, such resistance thermometer devices and/or thermopiles, and remain within the scope of the present disclosure.

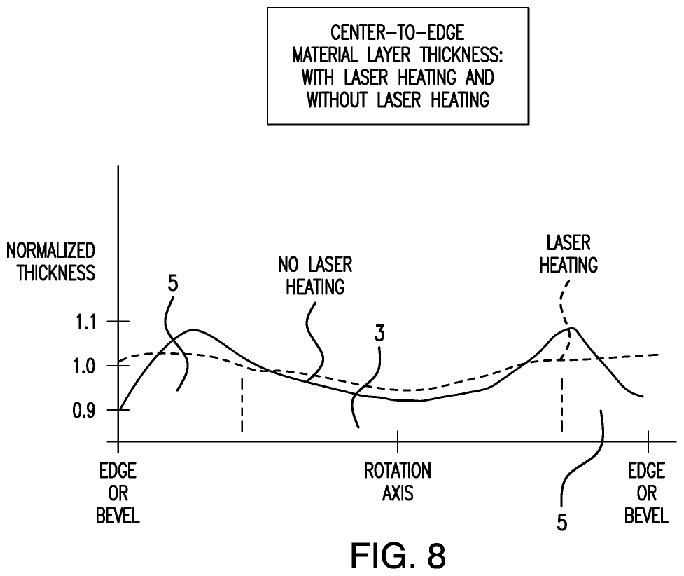

With reference to FIG. 8, cross-substrate thicknesses of material layers are shown without laser heating using laser illumination (shown in solid line) and with laser heating using the laser illumination 188 (shown in FIG. 3) during deposition of the material layer 4 (shown in FIG. 1) onto the substrate 2 (shown in FIG. 1). As shown on the left-hand and right-hand side of the solid line, material layer thickness may nominally roll-down in the portion of the material layer overlaying the peripheral portion 5 (shown in FIG. 4) of the substrate 2 of the with the solid line. The roll-down may be caused by emissivity differences between the peripheral portion 5 and the central portion 3 (shown in FIG. 4) associated with a pattern on the substrate 2, heat flux between the substrate 2 and the substrate support 104 (shown in FIG. 3) at the edge or bevel 8 (shown in FIG. 5) inducing temperature differentials within the peripheral portion 5 of the substrate 2. In certain examples, the peripheral portion 5 may have a width that is less than about 30 millimeters, or is less than about 20 millimeters, or even that is less than about 10 millimeters. As shown with dashed line, heating of the peripheral portion 5 of the substrate and the surface portion of the substrate radially outward of the edge or bevel 8 reduces (or eliminates) the roll-down in the thickness of the material layer 4 in the portion of the material layer 4 overlaying the peripheral portion 5 of the substrate 2. Advantageously, by locally heating both the peripheral portion 5 of the substrate 2 and the surface portion of the substrate support 104 radially outward of the peripheral portion 5, heat flux between the bevel or edge 8 of the substrate 2 may be reduced (or eliminated) using the laser illumination 188, reducing temperature variation within the edge portion 5 of the substrate 2 and improving temperature control of the substrate during deposition of the material layer 4 onto the substrate 2.

With reference to FIGS. 9 and 10, a chamber arrangement 200 is shown. The chamber arrangement 200 is similar to the chamber arrangement 100 (shown in FIG. 1) and additionally has a temperature sensor 135 including a rotating thermocouple 202 to throttle the laser illumination 188 provided by the laser source 106. The rotating thermocouple 202 is fixed in rotation R relative to the substrate support 104 and configured to acquire temperature of the substrate support 104. In this respect the rotating thermocouple 202 may abut the lower surface of the substrate support 104 at a location along the rotation axis 110 and provide a tactile temperature measurement 204 indicative of temperature of the lower surface of the substrate support 104. The rotating thermocouple 202 may be further connected to the controller 118 through a thermocouple lead 206, the thermocouple lead 206 through the shaft member 148 and in electrical communication with the wired or wireless link 168. Electrical communication may be through a slip ring assembly by way of example.

The controller 118 may be configured to throttle the laser illumination 188 provided by the laser source 106 using the tactile temperature measurement 204. For example, the controller 118 may (a) receive the tactile temperature measurement 204, (b) compare the temperature measurement to a temperature and power setting associations recorded in a lookup table 208 recorded on the memory 176, and (c) throttle the laser illumination 188 according to power setting associated with the temperature in the lookup table 208. As will be appreciated by those of skill in the art in view of the present disclosure, this enables compensating for thickness variation within the peripheral portion 5 of the substrate 2 according a process characterization, enable material layer thickness control along that shown in FIG. 8 with a singular rotating thermocouple, simplifying the chamber arrangement 200. As will also be appreciated by those of skill in the art in view of the present disclosure, the tactile temperature measurement 204 may employed using other operations to control the laser source 106 and remain within the scope of the present disclosure.

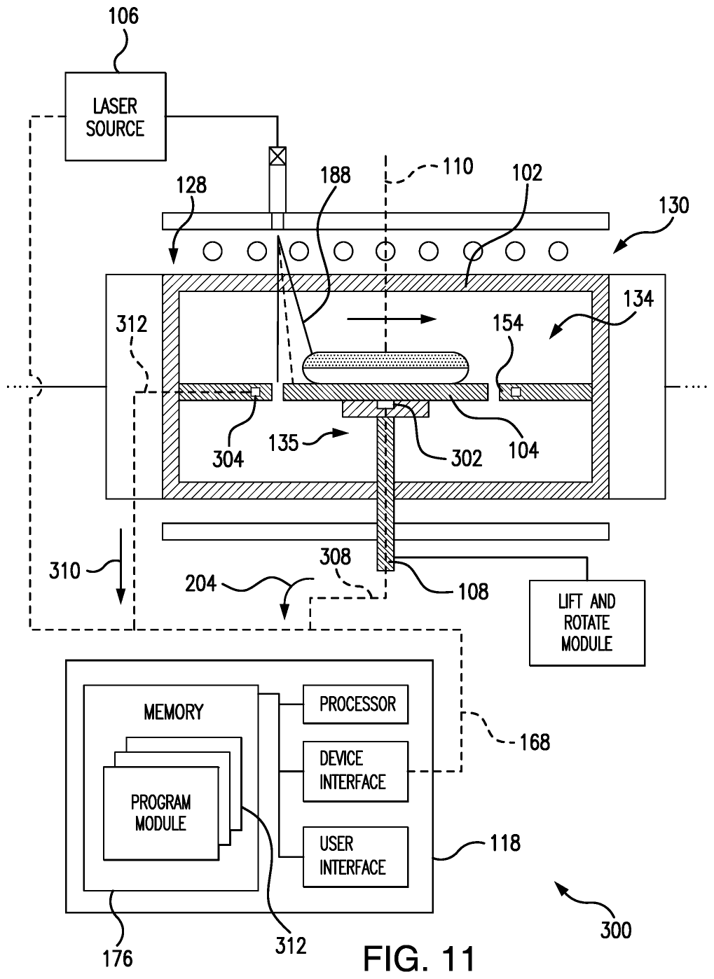

With reference to FIGS. 11 and 12, a chamber arrangement 300 is shown. The chamber arrangement 300 is similar to the chamber arrangement 100 (shown in FIG. 1) and additionally includes a temperature sensor 135 having a rotating thermocouple 302 and the static thermocouple 304 to throttle the laser illumination 188 provided by the laser source 106. The rotating thermocouple 302 may be arranged within the interior 134 of the chamber body 102 and configured to acquire a first temperature measurement 306. The rotating thermocouple 302 may be arranged within the lower chamber 152 and abut a lower surface of the substrate support 104. The rotating thermocouple 302 may be further disposed in communication with the controller 118 to provide the first temperature measurement 306 to the controller 118, for example through a first thermocouple lead 308 extending through the shaft member 148 and connected to the wired or wireless link 168. In certain examples, the lasing spot 194 may be radially offset from the rotating thermocouple 302.

The static thermocouple 304 may be arranged within the interior 134 of the chamber body 102 and is further configured to acquire a second temperature measurement 310 from within the interior 134 of the chamber body 102. In this respect the static thermocouple 304 may be arranged radially outward of the rotating thermocouple 302, for example, fixed relative to the chamber body 102. The static thermocouple 304 may be arranged within the interior of the divider 144 and circumferentially offset from the first thermocouple 320 about the rotation axis 110. The static thermocouple 304 may be further disposed in communication with the controller 118 to provide the second temperature measurement 310 to the controller 118, for example through a second thermocouple lead 312 extending through the divider 144 and connected to the wired or wireless link 168. It is contemplated that the lasing spot 194 may be longitudinally offset and/or laterally offset from the static thermocouple 304. It is also contemplated that, in accordance with certain examples, that the static thermocouple 304 be one of an array of thermocouples distributed circumferentially about the substrate support 104 and arranged radially outward of the divider aperture 154.

The controller 118 may be configured to throttle the laser illumination 188 provided by the laser source 106 using the first temperature measurement 306 and the second temperature measurement 310. In this respect the controller 118 may (a) receive the first temperature measurement 306 and the second temperature measurement 310 from the rotating thermocouple 302 and the static thermocouple 304, respectively; (b) determine a temperature differential using the first temperature measurement 306 and the second temperature measurement 310; and (c) compare the temperature differential to a predetermined temperature differential value 312 recorded on the memory 176. The controller 118 may further (d) throttle the laser illumination 188 when the temperature differential is greater than the predetermined temperature differential 312. As will be appreciated by those of skill in the art in view of the present disclosure, controlling the laser illumination 188 according using temperature measurements acquired by the rotating thermocouple 302 and the static thermocouple 304 enables limiting thickness variation that could otherwise be present in the material layer 4 due to emissivity differences that may between the central portion 3 and the peripheral portion 5 of the substrate 2 without employing an external temperature sensor, simplifying the chamber arrangement 300.

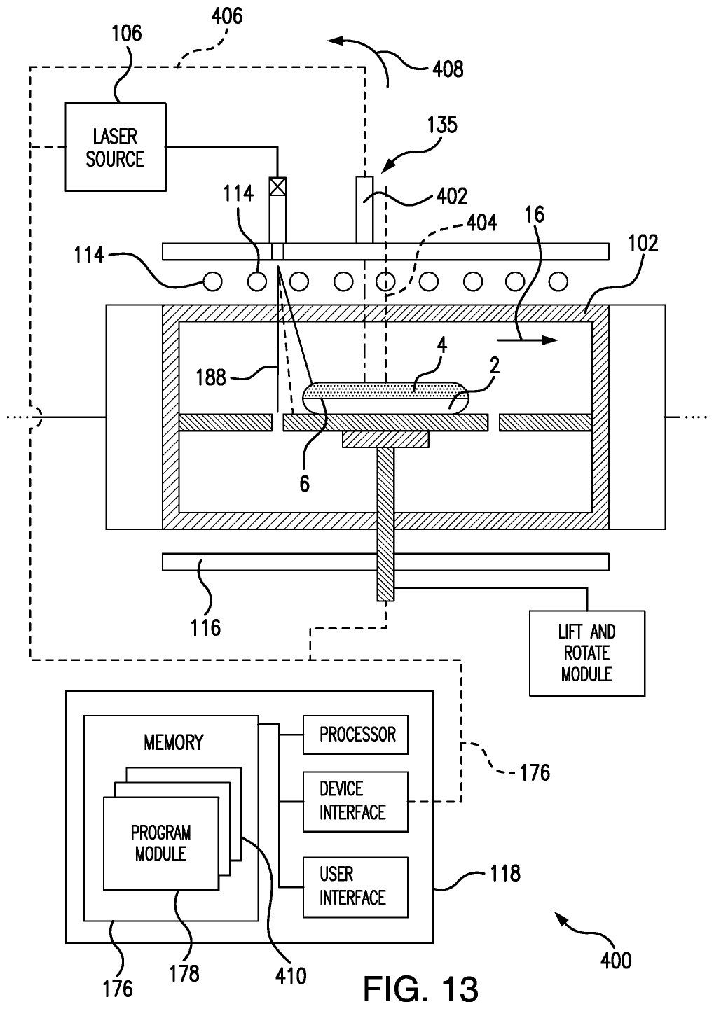

With reference to FIGS. 13 and 14, a chamber arrangement 400 is shown. The chamber arrangement 400 is similar to the chamber arrangement 100 (shown in FIG. 1) and additionally has a temperature sensor 135 including a pyrometer 402 to throttle the laser illumination 188 provided by the laser source 106. The pyrometer 402 is supported above the chamber body 102 and is optically coupled along an optical axis 404 to the upper surface 6 of the substrate 2 (or the material layer 4 during deposition onto the substrate 2) to acquire an optical temperature measurement 408 indicative of temperature of the substrate 2. The pyrometer 402 may be disposed in communication with controller 118, for example through a pyrometer lead 406 connected to the wired or wireless link 168, to provide the optical temperature measurement 408. The optical temperature measurement 408 may be acquired directly from the upper surface 6 of the substrate 2 and/or the material layer 4, for example from electromagnetic radiation emitted by the upper surface 6 of the substrate 2 and/or the material layer 4 during deposition onto the substrate 2. The optical temperature measurement 408 may be acquired in real-time with heating of the substrate 2, i.e., without delay due to conduction of heat through an intervening material. In certain examples, the optical axis 404 may intersect the central portion 3 of the substrate 2. In accordance with certain examples, the optical axis 404 may intersect the peripheral portion 5 of the substrate 2. It is contemplated that the optical axis 404 may intersect the substrate 2 at a location radially offset from the lasing spot 194. It is also contemplated that the optical axis 404 may intersect the substrate 2 at a location radially overlapping, and/or circumferentially offset, from the lasing spot 194.

The controller 118 may be configured to throttle the laser illumination 188 using the optical temperature measurement 408. In this respect the controller 118 may (a) receive the optical temperature measurement 408 from the optical pyrometer 402, (b) compare the optical temperature measurement 408 to a listing of predetermined temperature measurements associated with laser source power settings in a lookup table 410 recorded in one of the plurality of program modules 178 on the memory 176, (c) heat the substrate 2 using upper heater element array 114 and the lower heater element array 116 using the optical temperature measurement 408, and (d) throttle the laser illumination 188 according to a laser source power setting associated with the optical temperature measurement 408 to further heat the peripheral portion 5 of the substrate 2 using the laser source 106. As will be appreciated by those of skill in the art in view of the present disclosure, controlling the laser illumination 188 using the optical temperature measurement 408 enables limiting material layer thickness variation that could otherwise be present in the material layer 4 due to emissivity differences between the peripheral portion 5 and the central portion 3 of the substrate. For example, the upper heater element array 114 and/or the lower heater element array 116 may be controlled to heat the entirety of the substrate 2 using the optical temperature measurement 408, and the laser power setting associated with the optical temperature measurement 408 in the lookup table 410 employed to communicate additional heat to the peripheral portion 5 of the substrate 2 to compensate emissivity differences between the peripheral portion 5 and the central portion 3 of the substrate 2. As will also be appreciated by those of skill, the optical temperature measurement 408 may be employed in other regimes to control the laser source 106 and remain within the scope of the present disclosure.

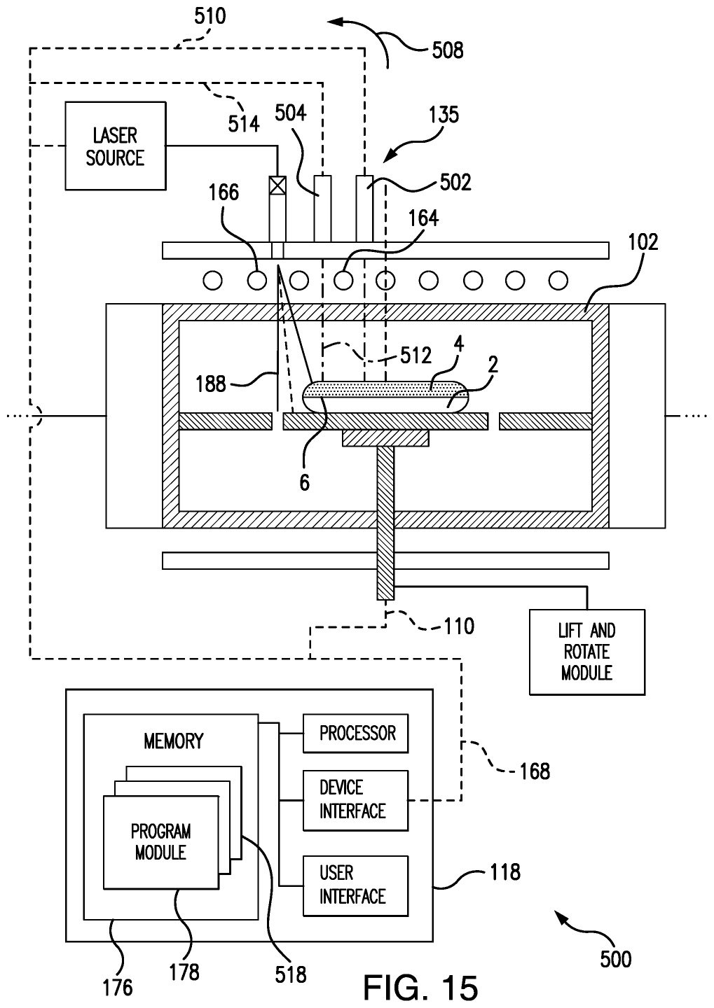

With reference to FIGS. 15 and 16, a chamber arrangement 500 is shown. The chamber arrangement 500 is similar to the chamber arrangement 100 (shown in FIG. 1) and additionally has a temperature sensor 135 including a center pyrometer 502 and an edge pyrometer 504 to throttle the laser illumination 188 provided by the laser source 106. The center pyrometer 502 is supported above the chamber body 102 and is optically coupled to the substrate 2 and/or the material layer 4 along a center optical axis 506 to acquire a center temperature measurement 508. In this respect it is contemplated that the center optical axis 506 intersect the central portion 3 of the substrate 2, for example along the rotation axis 110 or at a location radially offset from the rotation axis 110 and above the central portion 3 of the substrate 2. The center pyrometer 502 may connected to the controller 118, for example through a center pyrometer lead 510 connected to the wired or wireless link 168, to provide the center temperature measurement 508 to the controller 118. The edge pyrometer 504 may be similar to the center pyrometer 502, may additionally optically coupled to the substrate 2 and/or the material layer 4 along an edge optical axis 512, and may further be connected to the controller 118 by an edge pyrometer lead 514 to provide an edge temperature measurement 516 to the controller 118. It is contemplated that the edge optical axis 512 intersect the peripheral portion 5 of the substrate 2, for example, at a viewing location radially overlapping (at least partially) and circumferentially offset from the lasing spot 194.

The controller 118 may be configured to throttle the laser illumination 188 provided by the laser source 106 using the center temperature measurement 508 and the edge temperature measurement 516. In this respect the controller 118 may (a) receive the center temperature measurement 508 and the edge temperature measurement 516 from the center pyrometer 502 and the edge pyrometer 504, respectively; (b) calculate a center-to-edge differential using the center temperature measurement 508 and the edge temperature measurement 516; (c) compare the center-to-edge differential to a predetermined center-to-edge differential value 518 recorded in one of plurality of program modules 178 recorded on the memory 176; and (d) throttle the laser illumination 188 when the center-to-edge differential is greater than the predetermined center-to-edge differential value 518. The controller 118 may further (e) control the first upper heater element 162 and the second upper heater element 164 using the center temperature measurement 508, and control the at least one third upper heater element 166 using the edge temperature measurement 516. As will be appreciated by those of skill in the art in view of the present disclosure, supplementing differential heating of the substrate implemented through center temperature measurement 508 and the edge temperature measurement 516 may limit material layer thickness variation that could otherwise be present in the material layer 4 due to emissivity differences between the peripheral portion 5 and the central portion 3 of the substrate 2 resistant to resolution by differential heating techniques.

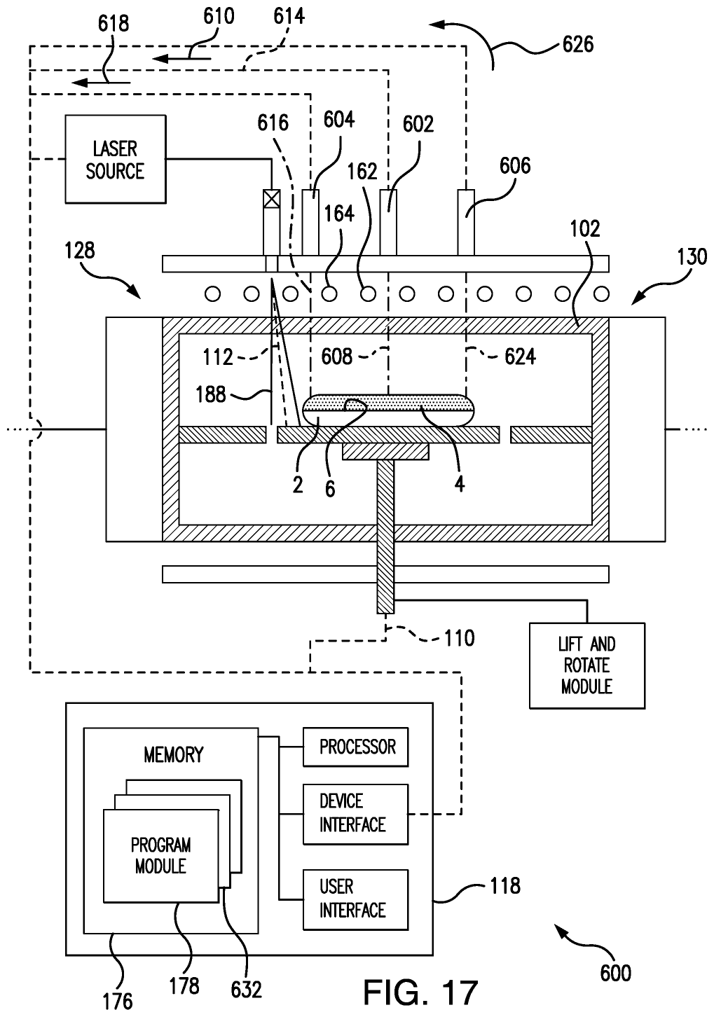

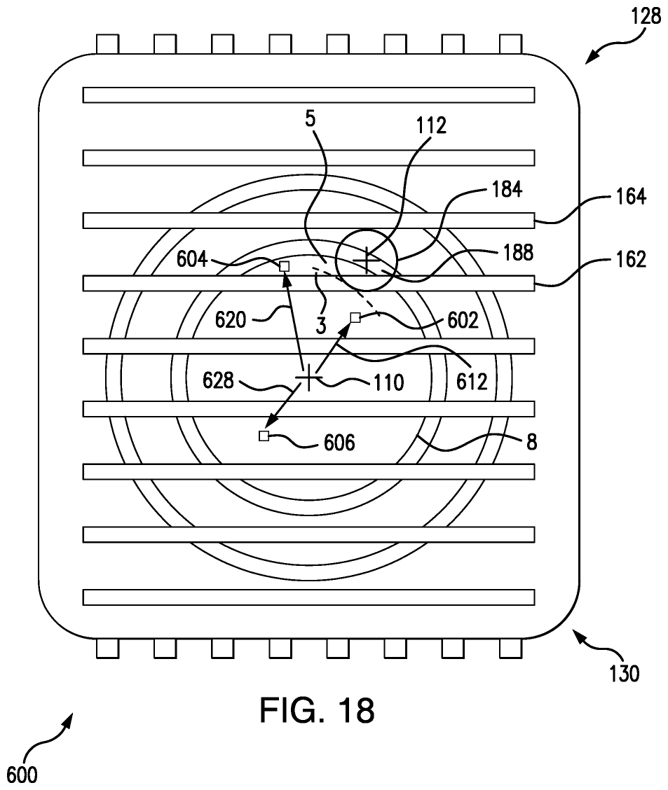

With reference to FIGS. 17 and 18, a chamber arrangement 600 is shown. The chamber arrangement 600 is similar to the chamber arrangement 100 (shown in FIG. 1) and additionally has a temperature sensor 135 including a center pyrometer 602, an edge pyrometer 604, and a middle pyrometer 606 to throttle the laser illumination 188 provided by the laser source 106. The center pyrometer 602 is supported above the chamber body 102, is optically coupled to the substrate 2 and/or the material layer 4 along a center optical axis 608, and is configured to acquire a center temperature measurement 610 of the central portion 3 of the substrate 2 and/or the material layer 4 during deposition thereon. The center optical axis 608 may intersect the central portion 3 of the substrate 2 along the rotation axis 110 or at a location radially offset from the rotation axis 110 by a center pyrometer radial offset 612. The center pyrometer 602 may be connected to the controller 118 by a center pyrometer lead 614 and/or the wired or wireless link 168 to provide the center temperature measurement 610 to the controller 118. The center temperature measurement 610 may be provided in real-time (i.e., without delay associated with conduction through a bulk material), the center pyrometer 602 thereby providing the center temperature measurement 610 in real-time with temperature change at the locations radially offset from the rotation axis 110 by the center pyrometer radial offset 612.

In certain examples the center pyrometer radial offset 612 may be less than 20 millimeters, of less than 15 millimeters, or even less than 10 millimeters. In accordance with certain examples, the center optical axis 608 may extend between the first upper heater element 162 and the exhaust end 130 of the chamber body 102. It is also contemplated that, in accordance with certain examples, the center optical axis 608 may extend between the first upper heater element 162 and the rotation axis 110. As will be appreciated by those of skill in the art in view of the present disclosure, center pyrometer radial offsets within these ranges allow the center pyrometer 602 to receive electromagnetic radiation emitted by the upper surface 6 of the substrate 2 directly, and with substantially no interference from the structure of the upper heater elements of the upper heater element array 114 supported between the center pyrometer 602 and the upper wall 120 (shown in FIG. 3) of the chamber body 102.

The edge pyrometer 604 is similar to the center pyrometer 602 and is additionally arranged along an edge optical axis 616. The edge optical axis 616 extends through the upper heater element array 114 (e.g., between the second upper heater element 164 and the at least one third upper heater element 166), intersects the substrate 2 (and the substrate support 104) radially inward of the lasing axis 112, and optically couples the edge pyrometer 604 to the peripheral portion 5 of the substrate 2 such that the edge pyrometer 604 may acquire an edge temperature measurement 618 from the peripheral portion 5 of the substrate 2 and/or the material layer 4 during deposition thereon. The edge optical axis 616 further intersects the substrate 2 (and the substrate support 104) at an edge pyrometer radial offset 620. It is contemplated that the edge pyrometer radial offset 620 be greater than the center pyrometer radial offset 612 and in this respect may be between about 100 millimeters and about 150 millimeters, or between about 120 millimeters and about 150 millimeters, or even between about 140 millimeters and about 150 millimeters. It is also contemplated that the edge pyrometer 604 provide the edge temperature measurement 618 to the controller 118, for example, through an edge pyrometer lead 622 connecting the edge pyrometer 604 to the controller 118.

The edge optical axis 616 may be circumferentially overlapped by the lasing spot 194, the edge temperature measurement 618 thereby indicative of heating of the peripheral portion 5 of the substrate 2 by the laser illumination 188. The edge optical axis 616 may be circumferentially offset from the lasing axis 112, which may limit noise potentially introduced into the edge temperature measurement 618 by stray light reflected by the bevel or edge 8 of the substrate 2. The edge optical axis 616 and the lasing axis 112 may extend between a common pair of longitudinally adjacent upper heater elements, enabling the edge pyrometer 604 to control the both the longitudinally adjacent upper heater elements and the laser source 106, simplifying heating of the substrate 2.

The middle pyrometer 606 is similar to the edge pyrometer 604 and is additionally arranged along a middle optical axis 624. The middle optical axis 624 extends through the upper heater element array 114, for example, between the second upper heater element 164 and first upper heater element 162 of the upper heater element array 114. It is contemplated that the middle optical axis 624 intersect the substrate 2 (and the substrate support 104) at a location radially between the center optical axis 608 and the edge optical axis 616, and that middle optical axis 624 optically couple the middle pyrometer 606 to the central portion 3 of the substrate 2 to acquire a middle temperature measurement 626 of the substrate 2 and/or the material layer 4 during deposition thereon. It is contemplated that the middle pyrometer 606 provide the middle temperature measurement 626 to the controller 118, for example, through a middle pyrometer lead 630 connecting the middle pyrometer 606 to the controller 118.

In certain examples, the middle optical axis 624 may be circumferentially offset from either (or both) the center optical axis 608 and the edge optical axis 616. In accordance with certain examples, the middle optical axis 624 may extend between a pair of longitudinally adjacent upper heater elements different from those passed through by the center optical axis 608 and the edge optical axis 616. For example, the middle optical axis 624 may extend between the first upper heater element 162 and the second upper heater element 164. It is also contemplated that the middle optical axis 624 intersect the substrate 2 (and the substrate support 104) at a middle pyrometer radial offset 628. The middle pyrometer radial offset 628 may be less than the edge pyrometer radial offset 620. The middle pyrometer radial offset 628 may be greater than the center pyrometer radial offset 612. For example, the middle pyrometer radial offset 628 may be between about 25 millimeters and about 100 millimeters, or between about 40 millimeters and about 80 millimeters, or even between about 50 millimeters and about 60 millimeters.

The controller 118 may be configured to throttle the laser illumination 188 using one or more of the center temperature measurement 610, the edge temperature measurement 618, and the middle temperature measurement 626. In certain examples, the controller 118 may throttle the laser illumination 188 using only the edge temperature measurement 618. In accordance with certain examples, the controller 118 may throttle the laser illumination 188 using the edge temperature measurement 618 and the center temperature measurement 610, for example, by determining a difference between the center temperature measurement 610 and the edge temperature measurement 618 and throttling the laser illumination 188 when the difference is greater than a predetermined temperature difference. As will be appreciated by those of skill in the art in view of the present disclosure, throttling the laser illumination 188 according a difference between the center temperature measurement 610 and the edge temperature measurement 618 may limit center-to-edge temperature variation between the peripheral portion 5 and the central portion 3 of the substrate 2 during deposition of the material layer 4 onto the upper surface 6 of the substrate 2.

It is also contemplated that the controller 118 may throttle the laser illumination 188 according to temperature gradient across the central portion 3 and the peripheral portion 5 of the substrate 2 using the center temperature measurement 610, the edge temperature measurement 618, and the middle temperature measurement 626. In this respect the controller 118 may (a) receive the center temperature measurement 610, the edge temperature measurement 618, and the middle temperature measurement 626; (b) determine a temperature gradient across the substrate 2 using the center temperature measurement 610, the edge temperature measurement 618, and the middle temperature measurement 626; and (c) compare the determined temperature gradient to a predetermined temperature gradient 632 recorded in one of the plurality of program modules 178 recorded on the memory 176. The controller 118 may further (d) throttle the laser illumination 188 incident on the peripheral portion 5 of the substrate 2 and the substrate support 104 when the determined temperature gradient is greater than the predetermined temperature gradient 632. Temperature gradient may be determined by fitting a curve to each of the center temperature measurement 610, the edge temperature measurement 618, and the middle temperature measurement 626; determining slope of a line tangent to the curve over at least the peripheral portion 5 of the substrate 2; and throttling the laser illumination to limit the greatest slope along at least the peripheral portion 5 of the substrate 2. As will be appreciated by those of skill in the art in view of the present disclosure, throttling the laser illumination 188 according to temperature gradient may limit (or eliminate) tendency of slip defects to develop in the material layer 4, such as in the portion of the material layer 4 in (or proximate) the peripheral portion 5 of the substrate 2, during the deposition of relatively thick (25 microns to 100 microns) epitaxial material layers.

With reference to FIGS. 19-22, a material deposition method 700 according to the present disclosure is shown. As shown in FIG. 19, the method 700 may include seating a substrate on a substrate support rotatably supported within a chamber body, e.g., seating the substrate 2 (shown in FIG. 1) on the substrate support 104 (shown in FIG. 3) within the chamber body 102 (shown in FIG. 3), as shown with box 702. The substrate may be heated using an upper heater element array supported above the chamber body and a lower heater element array supported below the chamber body, e.g., the upper heater element array 114 (shown in FIG. 3) and the lower heater element array 116 (shown in FIG. 3), as shown with box 704. A peripheral portion of the substrate and adjacent portion of the substrate support may be further heated using a lower source, e.g., the peripheral portion 5 (shown in FIG. 6) of the substrate and an adjacent surface portion of the substrate support further heated using the laser source 106 (shown in FIG. 3), as shown with box 706. The substrate may be exposed to a material layer precursor during heating, e.g., the substrate exposed to the material layer precursor 16 (shown in FIG. 1), and a material layer deposited onto the substrate during the heating, e.g., the material layer 4 (shown in FIG. 1), as shown with box 708 and box 710.

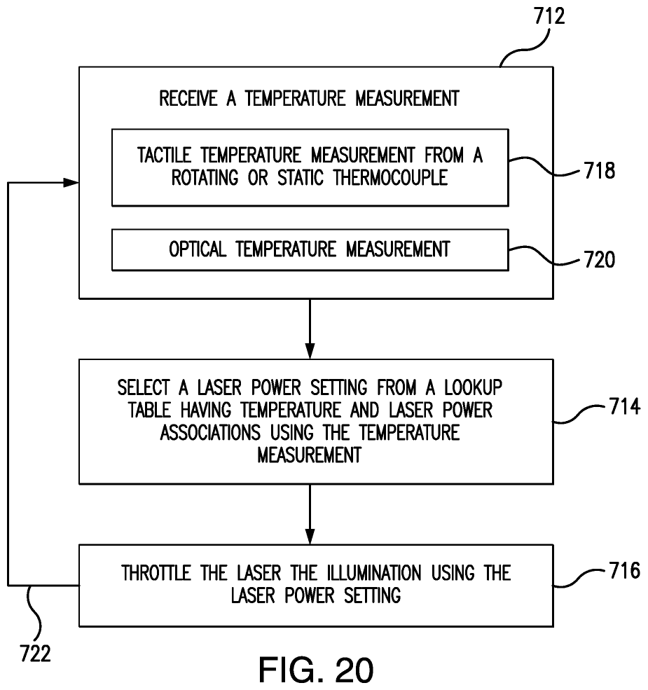

As shown with FIG. 20, the method 700 may include throttling the laser illumination using a temperature measurement indicative of temperature of the substrate during deposition of the material layer. In this respect a temperature measurement may be received from a temperature sensor, e.g., the temperature measurement 137 (shown in FIG. 3) received from the temperature sensor 135 (shown in FIG. 4), as shown with box 712. The temperature measurement may be compared to temperatures on a lookup table associated with predetermined laser power settings, e.g., the lookup table 208 (shown in FIG. 9), and the laser illumination throttled according to a predetermined laser power setting associated with the temperature measurement, as shown with box 714 and box 716. The temperature measurement may be acquired indirectly from the substrate, e.g., the tactile temperature measurement 204 (shown in FIG. 9) provided by the rotating thermocouple 202 (shown in FIG. 9), as shown with box 718. The temperature measurement may be acquired directly from the substrate, e.g., the optical temperature measurement 408 (shown in FIG. 13) acquired by the pyrometer 402 (shown in FIG. 13), as shown with box 720. The operations shown in FIG. 20 may be cyclically repeated during deposition of the material layer onto the substrate, for example to limit edge roll-up or edge roll-off otherwise characteristic of the deposition process, as shown with arrow 722.

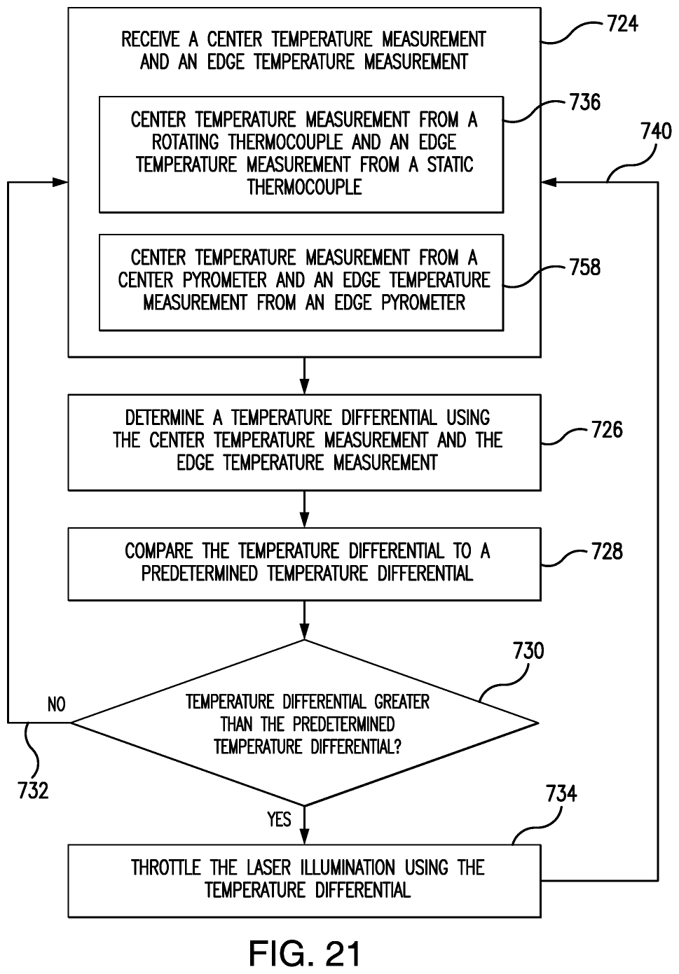

As shown with FIG. 21, the method 700 may include throttling the laser illumination using temperature measurements indicative of center-to-edge temperature variation radially across the surface of the substrate. In this respect a center temperature measurement and an edge temperature measurement may be acquired, as shown with box 724. A center-to-edge temperature differential may be determined using the center temperature measurement and the edge temperature measurement, as shown with box 726, and the center-to-edge temperature differential compared to a predetermined center-to-edge temperature differential, e.g., the predetermined temperature differential 518 (shown in FIG. 16), as shown with box 728. When the center-to edge temperature differential is less than the predetermined center-to-edge differential, power applied to the laser source may remain constant, as shown with box 730 and arrow 732. When the determined center-to-edge temperature differential is greater than the predetermined center-to-edge temperature differential the laser illumination may be throttled based on the determined center-to-edge temperature differential, as shown with boxes 730 and 734.

The center temperature measurement and the edge temperature measurement may be acquired indirectly from the substrate, e.g., the first temperature measurement 306 (shown in FIG. 11) acquired by the rotating thermocouple 302 (shown in FIG. 11) and the second temperature measurement 310 (shown in FIG. 11) acquired by the static thermocouple 304 (shown in FIG. 11), as shown with box 736. The center and edge temperature measurements may be acquired directly from the substrate, e.g., the center temperature measurement 508 (shown in FIG. 15) acquired from the center pyrometer 502 (shown in FIG. 15) and the edge temperature measurement 516 (shown in FIG. 15) acquired by the edge pyrometer 504 (shown in FIG. 15), as shown with box 738. The operations shown in FIG. 21 may be cyclically repeated during deposition of the material layer onto the substrate, for example, to limit edge roll-up or edge roll-off that may otherwise be imparted into the material layer due to the emissivity differences between the peripheral portion and center portion of a pattern on the substrate, as shown with arrow 732 and arrow 740.

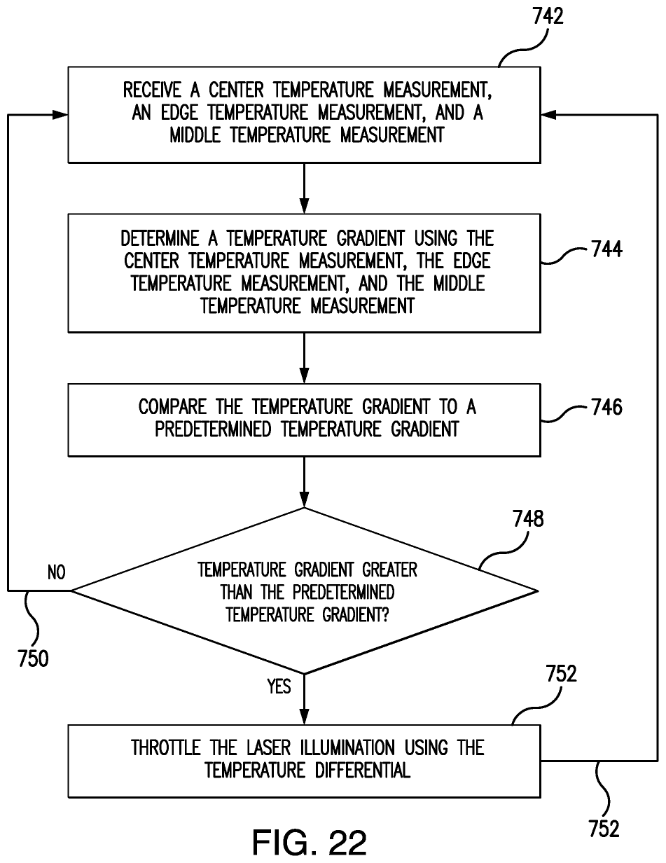

As shown with FIG. 22, the method 700 may include throttling the laser illumination using temperature measurements indicative of center-to-edge temperature gradient across the surface of the substrate. In this respect a center temperature measurement, an edge temperature measurement, and a middle temperature measurement may be acquired from the substrate, as shown with box 742. A center-to-edge temperature gradient may be determined using the center temperature measurement, the edge temperature measurement, and the middle temperature measurement, as shown with box 744. The center-to-edge temperature gradient may be compared to a predetermined center-to-edge temperature gradient, e.g., the predetermined center-to-edge temperature gradient 632 (shown in FIG. 17), as shown with box 746. Power applied to the laser source (and thereby intensity of the laser illumination incident upon the peripheral portion of the substrate) may remain constant when the center-to-edge temperature gradient is less than the predetermined center-to-edge gradient value, as shown with box 748 and arrow 750. The laser illumination may be throttled when the center-to edge temperature gradient is greater than the predetermined center-to-edge temperature gradient, as shown with box 748 and box 752.

The center temperature measurement may be acquired directly from the substrate, e.g., the center temperature measurement 610 (shown in FIG. 17) acquired using the center pyrometer 602 (shown in FIG. 17). The edge temperature measurement may be acquired directly from the substrate, e.g., the edge temperature measurement 618 (shown in FIG. 17) acquired using the edge pyrometer 604 (shown in FIG. 17). The middle temperature measurement may be acquired directly from the substrate, e.g., the middle temperature measurement 626 (shown in FIG. 17) acquired using the middle pyrometer 606 (shown in FIG. 17). The operations shown in FIG. 22 may be cyclically repeated during deposition of the material layer onto the substrate to limit edge roll-up or edge roll-off and/or crystallographic slip tendencies that may otherwise be characteristic of the deposition process, as shown with arrow 750 and arrow 754.

In some material layer deposition processes, such as in chemical vapor deposition techniques like epitaxy and in certain atomic layer deposition techniques, temperature variation across the substrate may influence variation in thickness of the material layer across the substrate. Material layer thickness variation across the substrate may in turn influence performance of semiconductor devices fabricated at various locations on the surface of the substrate. For example, semiconductor devices formed in the peripheral portion of a substrate where the material thickness exhibits roll-up or roll-down may perform differential than devices formed in the central portion of the substrate. This may be true in material layers used to form silicon channels, material layers formed from silicon doped with phosphorous or arsenic, and in silicon-germanium material layers formed in film stacks during the fabrication of gate-all-around and dynamic random access memory devices. And while differential heating may be employed to limit thickness variation, a need remains to further reduce thickness variation, such as on patterned substrates where the edge portion of the substrate may exhibit greater emissivity than the central portion of the substrate.

In examples described herein a laser source is employed to heat the edge portion of substrate during deposition of a material layer onto the substate. Laser illumination incident upper the edge portion of substate may heat the edge portion of the substrate, limiting (or eliminating) tendency of thickness of the material layer to roll-up or roll-down on the edge portion of the substrate. The laser illumination may be incident on both the edge portion of the substrate and a portion of the substrate support radially outward of the edge portion of the substrate, limiting thermal flux between the substrate and the substrate support that may otherwise be present due to emissivity differences between the substrate and the substrate support. In certain examples, the laser illumination may be throttled during material layer deposition using a tactile temperature measurement, such as from a rotating and/or a fixed thermocouple. In accordance with certain examples, the laser illumination may be throttled during material layer deposition using an optical temperature measurement, such as from one or more pyrometers supported above the substrate. It is contemplated that the laser illumination may be throttled according to temperature differential between the center portion and the edge portion of the substrate, such as using a center pyrometer and an edge pyrometer. It is also contemplated that that the laser illumination may be throttled according to temperature gradient between the center portion and the edge portion of the substrate, such as by acquiring additional temperature information from a middle pyrometer supported above substrate at location radially between the center pyrometer and the edge pyrometer.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A chamber arrangement, comprising:
a chamber body;
a substrate support arranged within the chamber body and supported for rotation about a rotation axis relative to the chamber body; and
a laser source arranged outside of the chamber body and optically coupled to the substrate along a lasing axis, wherein the lasing axis intersects the substrate support at a location radially outward from an outer periphery of a substrate seated on the substrate support.

2. The chamber arrangement of claim 1, wherein the lasing axis intersects the substrate support at a radial offset between about 150 millimeters and about 200 millimeters, or about 151 millimeters and about 170 millimeters, or about 151 millimeters and about 155 millimeters.

3. The chamber arrangement of claim 1, further comprising one or more lens element arranged along the lasing axis and coupling the laser source to both a peripheral portion of the substrate and the substrate support through an upper wall of the chamber body.

4. The chamber arrangement of claim 3, wherein the lens element defines a lasing spot overlaying a portion of the substrate and an adjacent portion of the substrate support.

5. The chamber arrangement of claim 4, wherein the lasing spot has a width that is between about 5 millimeters and about 50 millimeters, or between about 10 millimeters and about 40 millimeters, or is between about 15 millimeters and about 30 millimeters.

6. The chamber arrangement of claim 3, wherein the lens element defines a focal point, wherein the focal point is defined outside of the chamber body.

7. The chamber arrangement of claim 1, further comprising a reflector body supported above the chamber body and having a lasing aperture extending therethrough, wherein the lasing axis extends through the lasing aperture.

8. The chamber arrangement of claim 7, wherein the lasing aperture has a width that is between about 2 millimeters and about 20 millimeters, or between about 4 millimeters and about 15 millimeters, or is between about 4 millimeters and about 10 millimeters.

9. The chamber arrangement of claim 7, wherein the lasing aperture is spaced apart from the substrate support by between about 10 millimeters and about 100 millimeters, or by between about 10 millimeters and about 60 millimeters, or by between about 10 millimeters and about 40 millimeters.

10. The chamber arrangement of claim 7, further comprising a lens element arranged along the lasing axis and above the reflector body, wherein the lens element has a focal point, and wherein the focal point is defined within the lasing aperture.

11. The chamber arrangement of claim 1, further comprising a mount arranged along the lasing axis, wherein the mount defines a bore therethrough optically coupling the laser source to the substrate support and the substrate.

12. The chamber arrangement of claim 11, further comprising:
a lens element seated on the mount;
a reflector body with a lasing aperture supporting the mount;
wherein the mount registers the lens element to the lasing aperture and bore optically couples the lens element to the lasing aperture;
wherein the lasing aperture and the bore are fluidly separated from a coolant source plenum bounded by a mounting surface of the reflector body by the mount; and
wherein the lasing aperture fluidly couples the bore to a coolant supply plenum defined between a reflective surface of the reflector body and the chamber body.

13. The chamber arrangement of claim 12, further comprising:
a first sealing member arranged between the lens element and the mount, the first sealing member fluidly separating the bore from the coolant source plenum; and
a second sealing member arranged between the mount and the reflector body, the second sealing member fluidly separating the bore from the coolant source plenum,
wherein the reflector body defines at least one slot therethrough fluidly coupling the coolant source plenum to the coolant supply plenum, the bore fluidly coupled through the coolant supply plenum and the slot to the coolant source plenum.

14. The chamber arrangement of claim 12, further comprising an interlock switch connected to the mount and the lens element, wherein the interlock switch is operably connected to the laser source to remove power from the laser source when the lens element is separated from the mount.

15. The chamber arrangement of claim 14, wherein the interlock switch comprises:
a mount portion fixed relative to the mount; and
a lens portion fixed relative to the lens element, wherein the lens portion of the interlock switch is electromagnetically coupled to the mount portion of the interlock switch when the lens element is seated in the mount.

16. The chamber arrangement of claim 1, further comprising a temperature sensor operably connected to the laser source.

17. The chamber arrangement of claim 16, wherein the temperature sensor comprises a rotating thermocouple arranged within the interior of the chamber body and fixed in rotation relative to the substrate support.

18. The chamber arrangement of claim 16, wherein the temperature sensor comprises:
a rotating thermocouple arranged within the chamber body and fixed relative to the substrate support for rotating with the substrate about the rotation axis to provide a center temperature measurement of the substrate; and
a static thermocouple arranged within the interior of the chamber body and fixed relative to the chamber body, wherein the static thermocouple is arranged radially outward of the substrate support to provide an edge temperature measurement of the substrate.

19. The chamber arrangement of claim 16, wherein the temperature sensor comprises a pyrometer supported above the chamber body and arranged along an optical axis intersecting the substrate support, wherein the optical axis is radially inward of the lasing axis to acquire a center temperature measurement of a central portion the substrate.

20. The chamber arrangement of claim 17, wherein the pyrometer is a center pyrometer arranged along a center optical axis and the temperature sensor further comprises an edge pyrometer arranged along an edge optical axis, the edge pyrometer supported above the chamber body, the edge optical axis intersecting the substrate support radially inward of the center optical axis to acquire an edge temperature measurement of a peripheral portion of the substrate.

21. The chamber arrangement of claim 20, wherein the temperature sensor further comprises a middle pyrometer supported above the chamber body and arranged along a middle optical axis, the middle optical axis intersecting the substrate support radially between the center optical axis and the edge optical axis to acquire a middle temperature measurement of the central portion of the substrate.

22. The chamber arrangement of claim 1, further comprising a controller operably connected to the laser source and responsive to instructions recorded on a memory to:
seat the substrate on the substrate support;
heat the substrate and the substrate support using an upper heater element array supported above the chamber body and a lower heater element array supported below the chamber body;
further heat a peripheral portion of the substrate and an adjacent portion of the substrate using laser illumination from the laser source;
expose the substrate to a material layer precursor; and
deposit a material layer onto the substrate using the material layer precursor while heating the substrate with the upper heater element array, the lower heater element array, and the laser source.

23. The chamber arrangement of claim 1, wherein the laser source has a wavelength that is between about 700 nanometers and about 900 nanometers, or is between about 740 nanometers and about 860 nanometers, or is between about 780 nanometers and about 820 nanometers.

24. The chamber arrangement of claim 1, wherein the laser source has an output power than is between about 140 watts and about 200 watts, or is between about 150 watts and about 190 watts, or is between about 160 watts and about 180 watts.

25. A semiconductor processing system, comprising:
a precursor delivery arrangement including a silicon-containing precursor;
a chamber arrangement as recited in claim 1 connected to the precursor delivery arrangement, wherein the substrate support is configured to support an edge or bevel of the substrate during deposition of an epitaxial material layer onto an upper surface of the substrate using the silicon-containing precursor;
one or more lens element arranged along the lasing axis, wherein the one or more lens element optically couples the laser source to the substrate support through an upper wall of the chamber body;
a reflector body supported above the chamber body and having an aperture extending therethrough, wherein the lasing axis extends through the aperture;
a mount arranged along the lasing axis and defining a bore therethrough, the bore optically coupling the laser source to the substrate support;
a temperature sensor operably connected to the laser source and configured to acquire temperature of the substrate seated on the substrate support; and
a controller operably connected to the laser source and disposed in communication with the temperature sensor, the controller responsive to instructions recorded on a memory to:
seat the substrate on the substrate support;
heat the substrate and the substrate support using an upper heater element array supported above the chamber body and a lower heater element array supported below the chamber body;
further heat a peripheral portion of the substrate and an adjacent portion of the substrate using laser illumination from the laser source;
expose the substrate to a material layer precursor; and
deposit a material layer onto the substrate using the material layer precursor while heating the substrate with the upper heater element array, the lower heater element array, and the laser source.

26. The semiconductor processing system of claim 25, wherein the temperature sensor comprises:
a rotating thermocouple fixed relative to the substrate support;
a static thermocouple fixed relative to the chamber body; and
wherein the rotating thermocouple and the static thermocouple are both operably connected to the laser source.

27. The semiconductor processing system of claim 25, wherein the temperature sensor comprises:
a center pyrometer supported above the chamber body and optically coupled to a central portion of the substrate by a center optical axis;
an edge pyrometer supported above the chamber body and optically coupled to the peripheral portion of the substrate by an edge optical axis, the edge optical axis located radially between the lasing axis and the rotation axis;
a middle pyrometer supported above the chamber body and optically coupled to the central portion of the substrate by a middle optical axis, the middle optical axis located radially between the center optical axis and the edge optical axis; and
wherein the center pyrometer, the edge pyrometer, and the middle pyrometer are each operably connected to the laser source.

28. A material layer deposition method, comprising:
at a chamber arrangement including a chamber body, a substrate support arranged within the chamber body and supported for rotation about a rotation axis relative to the chamber body, and a laser source arranged outside of the chamber body and optically coupled to the substrate along a lasing axis that intersects the substrate support at a location radially outward from an outer periphery of a substrate seated on the substrate support,
seating the substrate on the substrate support;
heating the substrate and the substrate support using an upper heater element array supported above the chamber body and a lower heater element array supported below the chamber body;
further heating a peripheral portion of the substrate and an adjacent portion of the substrate using laser illumination from the laser source;
exposing the substrate to a material layer precursor; and
depositing a material layer onto the substrate using the material layer precursor while heating the substrate with the upper heater element array, the lower heater element array, and the laser source.

29. The method of claim 28, further comprising throttling the laser illumination using a temperature measurement acquired from one of a thermocouple fixed relative to the substrate support and a pyrometer supported above the chamber body and optically coupled to the substrate by an optical axis.

30. The method of claim 28, further comprising:
acquiring a center temperature measurement using a center pyrometer supported above the chamber body and optically coupled to a center portion of the substrate by a center optical axis;
acquiring an edge temperature measurement using an edge pyrometer supported above the chamber body optically coupled to a peripheral portion of the substrate by an edge optical axis;
determining a center-to-edge temperature differential using the center temperature measurement and the edge temperature measurement; and
comparing the center-to-edge temperature differential to a predetermined center-to-edge temperature differential; and
throttling the laser illumination when the center-to-edge differential is greater than the predetermined center-to-edge temperature differential.
